(19) United States
(12) Patent Application Publication
(10) Pub. No.: US 2024/0196600 A1
(43) Pub. Date: Jun. 13, 2024

(54) SEMICONDUCTOR MEMORY DEVICES

(71) Applicant: Samsung Electronics Co., Ltd., Suwon-si (KR)

(72) Inventors: Jeongmin Jin, Suwon-si (KR); Sohyang Lee, Suwon-si (KR); Sohee Choi, Suwon-si (KR); Jinseo Choi, Suwon-si (KR)

(21) Appl. No.: 18/517,917

(22) Filed: Nov. 22, 2023

(30) Foreign Application Priority Data
Dec. 13, 2022 (KR) 10-2022-0174187

(51) Int. Cl. H10B 12/00

(52) U.S. Cl. CPC H10B 12/482; H10B 12/315; H10B 12/50

(57) ABSTRACT

A semiconductor memory device includes a substrate including a plurality of active regions in a memory cell region, a plurality of bit line structures extending in parallel with each other in a first horizontal direction in the memory cell region, a plurality of buried contacts respectively and electrically connected to the active regions and partially filling a space between the bit line structures, a plurality of lower landing pads in the space between the bit line structures and respectively on the buried contacts, a landing pad insulating structure in contact with the bit line structures and the lower landing pads and including a plurality of landing pad holes, a plurality of upper landing pads respectively filling the landing pad holes and respectively connected to the lower landing pads, and a plurality of capacitor structures.

### CROSS-REFERENCE TO RELATED APPLICATION

This application is based on and claims priority under 35 U.S.C. § 119 to Korean Patent Application No. 10-2022-0174187, filed on Dec. 13, 2022, in the Korean Intellectual Property Office, the disclosure of which is incorporated by reference herein in its entirety.

### BACKGROUND

Aspects of the inventive concept relate to semiconductor memory devices, and more particularly, to semiconductor memory devices having a capacitor structure.

With the rapid development of the electronics industry and user needs, electronic equipment is becoming lighter and more compact. Accordingly, semiconductor memory devices used in electronic equipment are required to have a high integration density, and thus, the design rules for the components of semiconductor memory devices have been decreased. Therefore, it is difficult to secure the reliability of semiconductor memory devices.

### SUMMARY

Aspects of the inventive concept provide a semiconductor memory device capable of simplifying manufacturing processes thereof and securing the reliability thereof.

According to an aspect of the inventive concept, there is provided a semiconductor memory device including a substrate including a plurality of active regions in a memory cell region, a plurality of bit line structures extending in parallel with each other in a first horizontal direction in the memory cell region, a plurality of buried contacts respectively and electrically connected to the plurality of active regions, the plurality of buried contacts partially filling a space between the plurality of bit line structures, a plurality of lower landing pads in the space between the plurality of bit line structures and respectively on the plurality of buried contacts, a landing pad insulating structure in contact with the plurality of bit line structures and the plurality of lower landing pads, the landing pad insulating structure including a plurality of landing pad holes, a plurality of upper landing pads respectively filling the plurality of landing pad holes and respectively connected to the plurality of lower landing pads, and a plurality of capacitor structures including a plurality of lower electrodes respectively and electrically connected to the plurality of upper landing pads, an upper electrode, and a capacitor dielectric layer between the plurality of lower electrodes and the upper electrode.

According to another aspect of the inventive concept, there is provided a semiconductor memory device including a substrate including a plurality of active regions in a memory cell region and a peripheral active region in a peripheral region, a plurality of bit line structures extending in parallel with each other in a first horizontal direction in the memory cell region, a plurality of buried contacts respectively and electrically connected to the plurality of active regions, the plurality of buried contacts partially filling a space between the plurality of bit line structures, a plurality of lower landing pads in the space between the plurality of bit line structures and respectively on the plurality of buried contacts, a landing pad insulating structure in contact with the plurality of bit line structures and the plurality of lower landing pads, the landing pad insulating structure including a plurality of landing pad holes, a plurality of upper landing pads respectively filling the plurality of landing pad holes and respectively connected to the plurality of lower landing pads, a gate line in the peripheral region, a peripheral bit line insulating structure on the gate line, the peripheral bit line insulating structure including a plurality of peripheral bit line recesses, and a plurality of peripheral bit lines respectively filling the plurality of peripheral bit line recesses, wherein a top surface of each of the plurality of upper landing pads, a top surface of the landing pad insulating structure, a top surface of each of the plurality of peripheral bit lines, and a top surface of the peripheral bit line insulating structure are coplanar with one another at the same vertical level.

According to a further aspect of the inventive concept, there is provided a semiconductor memory device including a substrate including a plurality of active regions in a memory cell region and a peripheral active region in a peripheral region, a plurality of word lines respectively in a plurality of word line trenches in the substrate, the plurality of word line trenches extending in parallel with each other in a first horizontal direction in the memory cell region, a plurality of bit line structures extending on the plurality of word lines in parallel with each other in a second horizontal direction that is perpendicular to the first horizontal direction, wherein each of the plurality of bit line structures includes a bit line, an insulating capping line covering the bit line, and a pair of insulating spacer structures respectively covering opposite side walls of each of the bit line and the insulating capping line, a plurality of buried contacts respectively and electrically connected to the plurality of active regions, the plurality of buried contacts partially filling a space between the plurality of bit line structures, a plurality of lower landing pads in the space between the plurality of bit line structures and respectively on the plurality of buried contacts, a landing pad insulating structure in contact with the plurality of bit line structures and the plurality of lower landing pads, the landing pad insulating structure including a plurality of landing pad holes, a plurality of upper landing pads respectively filling the plurality of landing pad holes and respectively connected to the plurality of lower landing pads, a plurality of capacitor structures including a plurality of lower electrodes respectively and electrically connected to the plurality of upper landing pads, an upper electrode, and a capacitor dielectric layer between the plurality of lower electrodes and the upper electrode, a gate line in the peripheral region, a filling insulation layer in the peripheral region, the filling insulation layer covering the substrate and the gate line and including a plurality of contact holes, a plurality of contact plugs respectively filling the plurality of contact holes and electrically connected to the peripheral active region, a peripheral bit line insulating structure on the gate line, the peripheral bit line insulating structure including a plurality of peripheral bit line recesses in communication with the plurality of contact holes, respectively, and a plurality of peripheral bit lines respectively filling the plurality of peripheral bit line recesses and electrically connected to the plurality of contact plugs, wherein the landing pad insulating structure includes a plurality of insulating grooves in a lower portion thereof, the plurality of insulating grooves being respectively filled with the plurality of bit line structures, and the plurality of peripheral bit lines pass through the peripheral bit line insulating structure and extend inside an upper portion of the filling insulation layer.

### BRIEF DESCRIPTION OF THE DRAWINGS

Embodiments will be more clearly understood from the following detailed description taken in conjunction with the accompanying drawings in which:

FIG. 1 is a diagram of a semiconductor memory device according to embodiments;

FIG. 2 is a schematic plane layout of main components of a semiconductor memory device, according to embodiments;

FIGS. 3A to 3E, FIGS. 4A to 4E, FIGS. 5A to 5E, FIGS. 6A to 6E, FIGS. 7A to 7E, FIGS. 8A to 8E, FIGS. 9A to 9E, FIGS. 10A to 10E, FIGS. 11A to 11E, and FIGS. 12A to 12E are cross-sectional views of sequential stages in a method of manufacturing a semiconductor memory device, according to embodiments;

FIGS. 13A to 13E are cross-sectional views of a semiconductor memory device according to embodiments;

FIGS. 14A and 14B are enlarged cross-sectional views of respective portions of a semiconductor memory device, according to embodiments; and

FIGS. 15A and 15B are enlarged cross-sectional views of respective portions of a semiconductor memory device, according to embodiments.

### DETAILED DESCRIPTION OF THE EMBODIMENTS

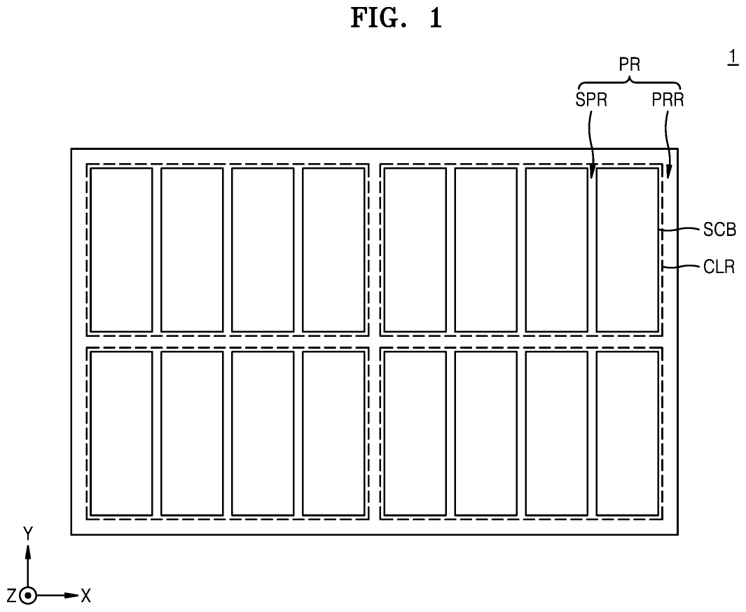

FIG. 1 is a diagram of a semiconductor memory device according to embodiments.

Referring to FIG. 1, a semiconductor memory device 1 may include a cell region CLR, in which memory cells are arranged, and a main peripheral region PRR surrounding the cell region CLR.

According to an embodiment, the cell region CLR may include sub peripheral regions SPR separating cell blocks SCB. A plurality of memory cells may be arranged in each of the cell blocks SCB. Here, a cell block SCB may refer to a region in which memory cells are regularly arranged at uniform intervals and may be referred to as a sub cell block.

Logic cells for input/output of electrical signals to/from the memory cells may be arranged in the main peripheral region PRR and each of the sub peripheral regions SPR. In some embodiments, the main peripheral region PRR may be referred to as a peripheral circuit region, and each sub peripheral region SPR may be referred to as a core circuit region. A peripheral region PR may include the main peripheral region PRR and the sub peripheral regions SPR. In other words, the peripheral region PR may correspond to a core and peripheral circuit region including a peripheral circuit region and a core circuit region. In some embodiments, at least a portion of each sub peripheral region SPR may be used only to separate cell blocks SCB from each other.

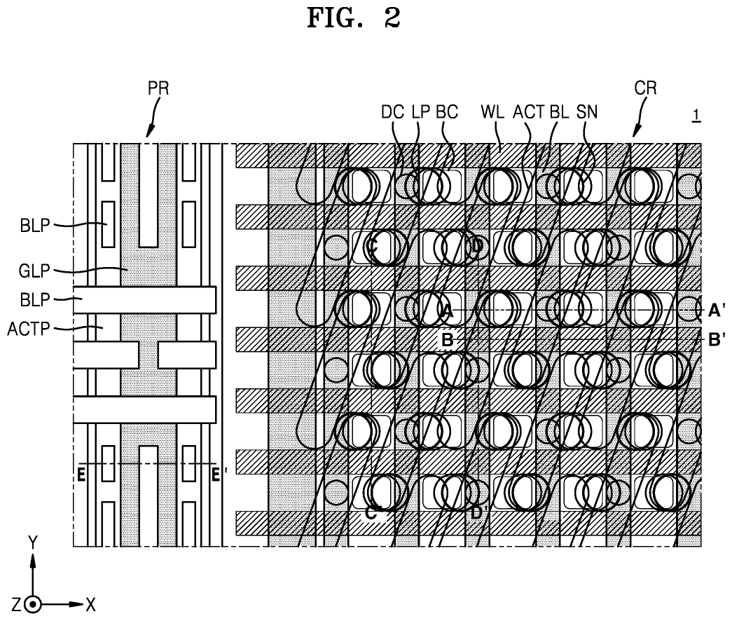

FIG. 2 is a schematic plane layout of main components of a semiconductor memory device, according to embodiments.

Referring to FIG. 2, the semiconductor memory device 1 may include a memory cell region CR and a peripheral region PR. The semiconductor memory device 1 may include a plurality of active regions ACT in the memory cell region CR and a peripheral active region ACTP in the peripheral region PR. The memory cell region CR may correspond to a cell block SCB, in which a plurality of memory cells are arranged in FIG. 1. The peripheral region PR may correspond to the peripheral region PR including the main peripheral region PRR and the sub peripheral regions SPR in FIG. 1.

In some embodiments, each of the active regions ACT in the memory cell region CR may have a long axis in a diagonal direction with respect to a first horizontal direction (the X direction) and a second horizontal direction (the Y direction), which is perpendicular to the first horizontal direction (the X direction).

A plurality of word lines WL may extend across the active regions ACT to be parallel with each other in the first horizontal direction (the X direction) in the memory cell region CR. A plurality of bit lines BL may extend over the word lines WL to be parallel with each other in the second horizontal direction (the Y direction) that crosses the first horizontal direction (the X direction). Each of the bit lines BL may be electrically connected to an active region ACT through a direct contact DC.

In some embodiments, a plurality of buried contacts BC may be between two adjacent bit lines BL among the bit lines BL. In some embodiments, the buried contacts BC may be arranged in line in each of the first horizontal direction (the X direction) and the second horizontal direction (the Y direction).

A plurality of landing pads LP may be respectively on the buried contacts BC. The landing pads LP may at least partially overlap with the buried contacts BC. In some embodiments, each of the landing pads LP may extend to above one of two adjacent bit lines BL.

A plurality of storage nodes SN may be respectively on the landing pads LP. The storage nodes SN may be above the bit lines BL. Each of the storage nodes SN may correspond to a lower electrode of a capacitor. Each storage node SN may be electrically connected to an active region ACT through a landing pad LP and a buried contact BC.

For convenience of illustration, other components than the peripheral active region ACTP, a plurality of gate line patterns GLP, and a plurality of peripheral bit lines BLP are omitted from the peripheral region PR in FIG. 2.

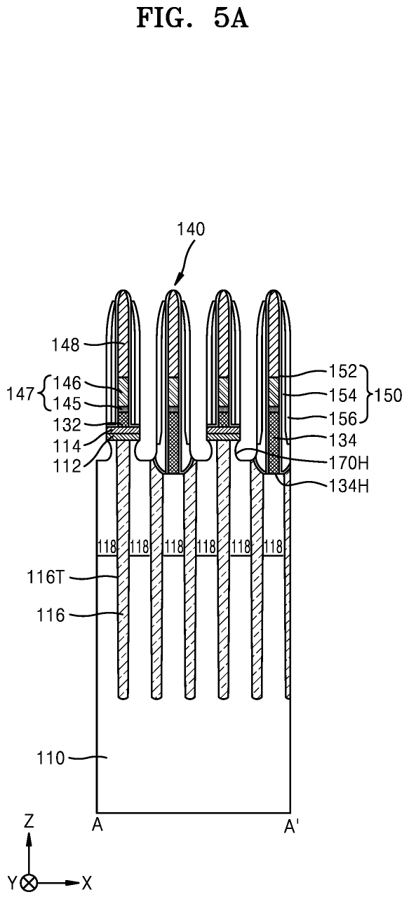

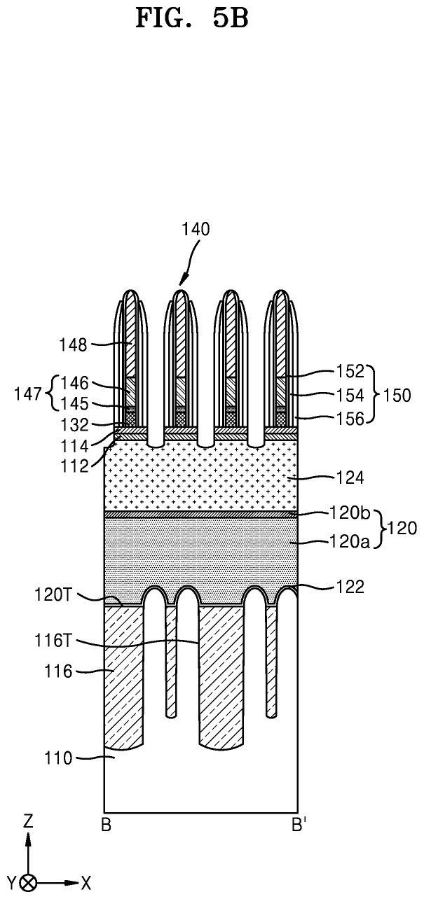

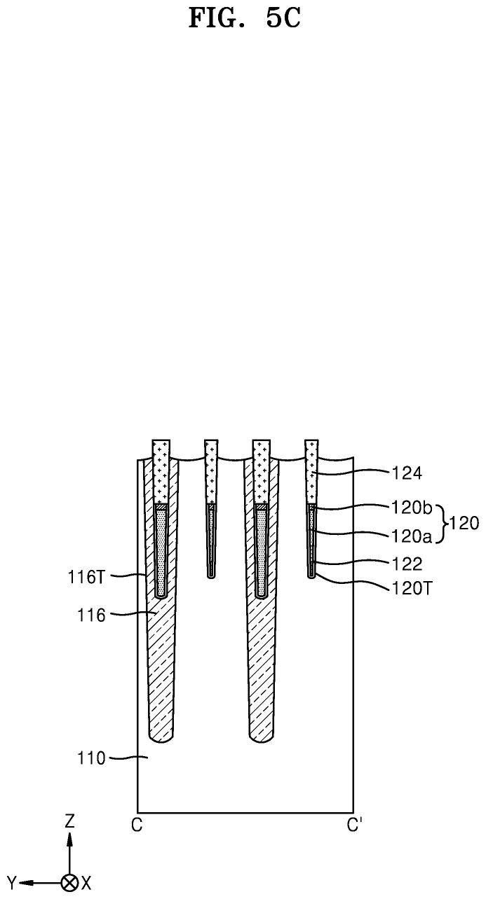

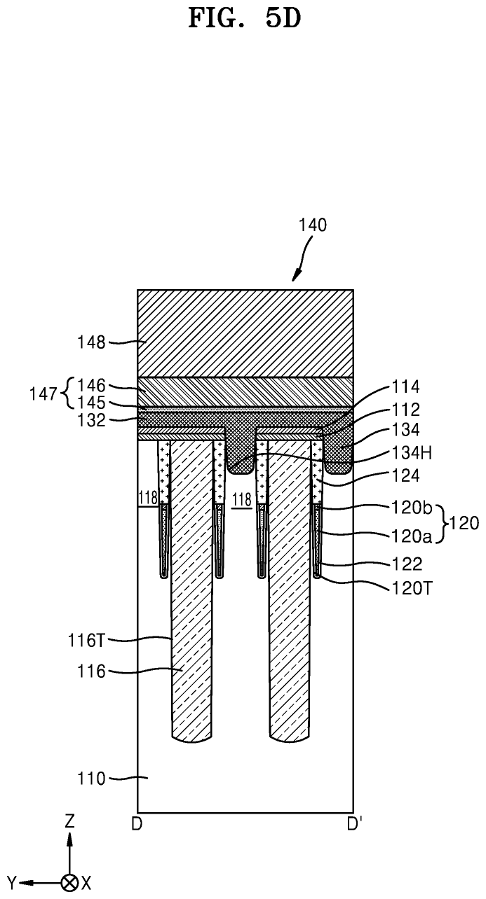

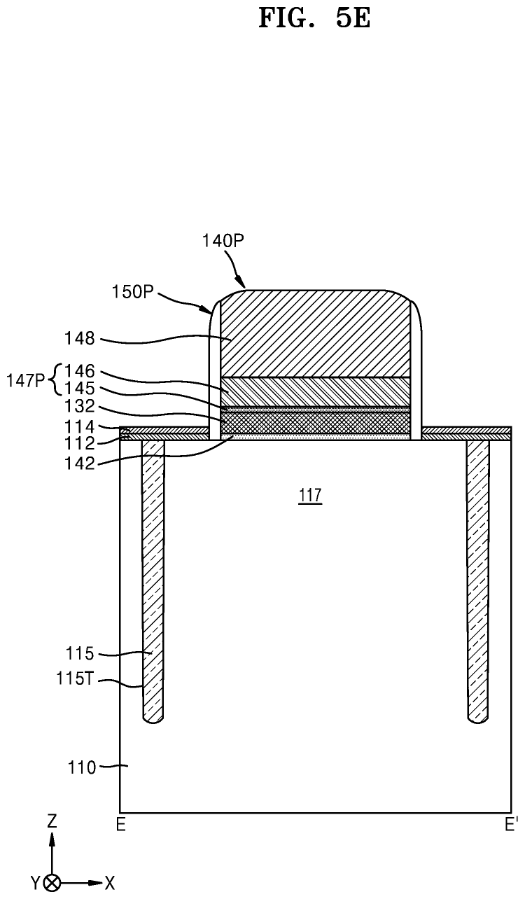

The gate line patterns GLP may be in the peripheral active region ACTP of the peripheral region PR. Although it is illustrated in FIG. 2 that a gate line pattern GLP extends in the second horizontal direction (the Y direction) in the peripheral active region ACTP and substantially has a constant width in the first horizontal direction (the X direction), embodiments are not limited thereto. For example, a plurality of gate line patterns GLP may be arranged in the peripheral active region ACTP of the peripheral region PR, and each of the gate line patterns GLP may have a different width than other gate line patterns GLP, may have a variable width, may have a curve, or may extend in a different direction than the other gate line patterns GLP. Although it is illustrated in FIG. 2 that a plurality of gate line patterns GLP are respectively in only a plurality of peripheral active regions ACTP, embodiments are not limited thereto. For example, at least some of the gate line patterns GLP may extend to the outside of the peripheral active regions ACTP, i.e., a peripheral isolation film 115 (in FIG. 5E).

At least a portion of a gate line pattern GLP and at least a portion of a bit line BL may be at the same vertical level as each other. In some embodiments, the gate line pattern GLP may include the same material as the bit line BL, or at least a portion of the gate line pattern GLP and at least a portion of the bit line BL may include the same material as each other. For example, at least a portion of the gate line pattern GLP and at least a portion of the bit line BL may be formed by the same process.

The peripheral bit lines BLP may be on the gate line pattern GLP in the peripheral region PR. At least some of the peripheral bit lines BLP may extend crossing the gate line pattern GLP. Although it is illustrated in FIG. 2 that each of some peripheral bit lines BLP extends in the second horizontal direction (the Y direction) on the gate line pattern GLP and substantially has a constant width in the first horizontal direction (the X direction) and each of the other peripheral bit lines BLP extends in the first horizontal direction (the X direction) on the gate line pattern GLP and substantially has a constant width in the second horizontal direction (the Y direction), embodiments are not limited thereto. For example, the peripheral bit lines BLP may have various or variable widths, may have curves, or may extend in various directions.

At least a portion of a peripheral bit line BLP and at least a portion of a landing pad LP may be at the same vertical level as each other. In some embodiments, the peripheral bit line BLP may include the same material as the landing pad LP, or at least a portion of the peripheral bit line BLP and at least a portion of the landing pad LP may include the same material as each other. For example, at least a portion of the peripheral bit line BLP and at least a portion of the landing pad LP may be formed by the same process.

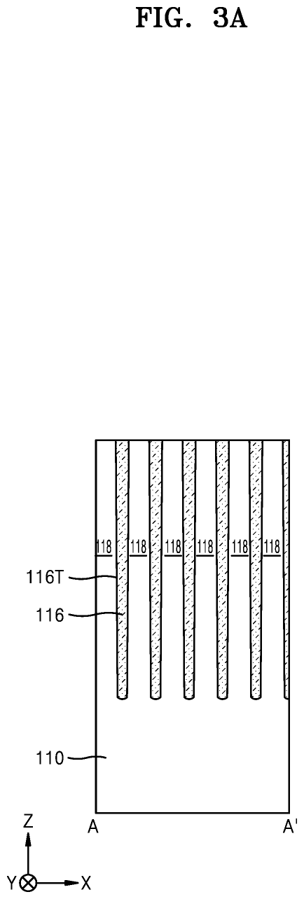

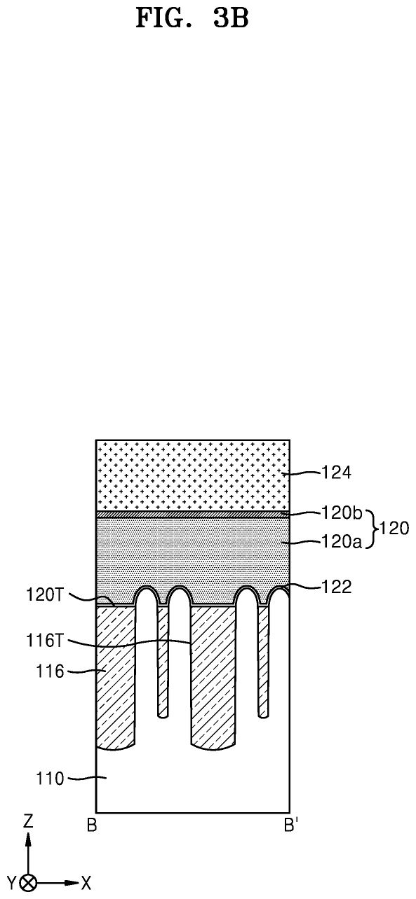

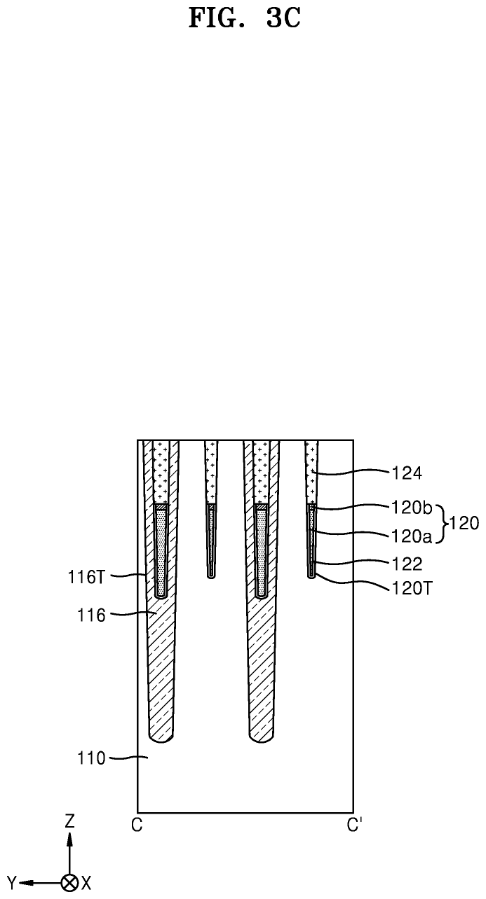

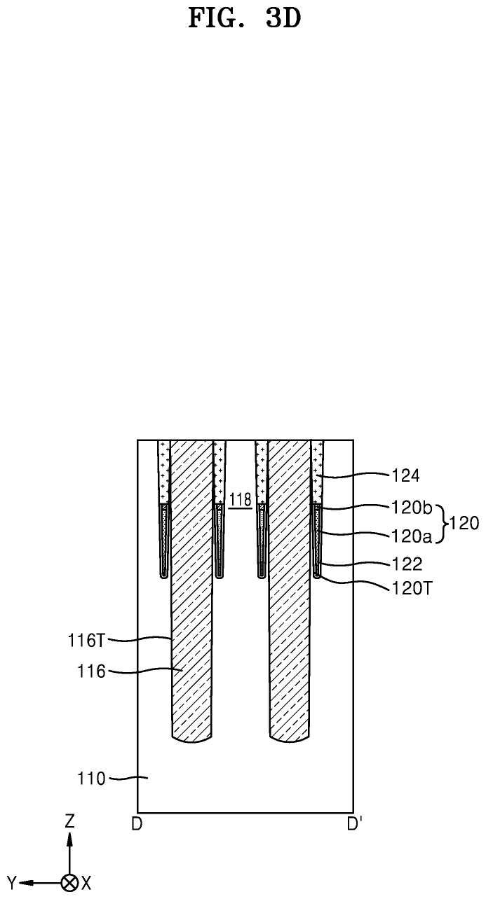

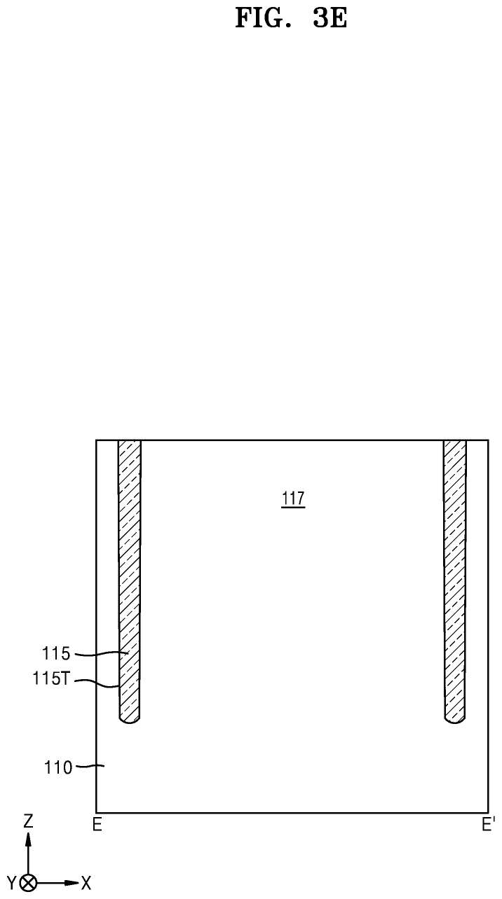

FIGS. 3A to 3E, FIGS. 4A to 4E, FIGS. 5A to 5E, FIGS. 6A to 6E, FIGS. 7A to 7E, FIGS. 8A to 8E, FIGS. 9A to 9E, FIGS. 10A to 10E, FIGS. 11A to 11E, and FIGS. 12A to 12E are cross-sectional views of sequential stages in a method of manufacturing a semiconductor memory device, according to embodiments. In detail, FIGS. 3A, 4A, 5A, 6A, 7A, 8A, 9A, 10A, 11A, and 12A are cross-sectionals views taken along line A-A′ in FIG. 2. FIGS. 3B, 4B, 5B, 6B, 7B, 8B, 9B, 10B, 11B, and 12B are cross-sectionals views taken along line B-B′ in FIG. 2. FIGS. 3C, 4C, 5C, 6C, 7C, 8C, 9C, 10C, 11C, and 12C are cross-sectionals views taken along line C-C′ in FIG. 2. FIGS. 3D, 4D, 5D, 6D, 7D, 8D, 9D, 10D, 11D, and 12D are cross-sectionals views taken along line D-D′ in FIG. 2. FIGS. 3E, 4E, 5E, 6E, 7E, 8E, 9E, 10E, 11E, and 12E are cross-sectionals views taken along line E-E′ in FIG. 2.

Referring to FIGS. 3A to 3E, an isolation trench 116T and a peripheral isolation trench 115T may be formed in a substrate 110, and an isolation film 116 filling the isolation trench 116T and a peripheral isolation film 115 filling the peripheral isolation trench 115T may be formed.

In some embodiments, the substrate 110 may include, for example, silicon (Si), crystalline Si, polycrystalline Si, or amorphous Si. In some embodiments, the substrate 110 may include a semiconductor element, such as germanium (Ge), or at least one compound semiconductor selected from silicon germanium (SiGe), silicon carbide (SiC), gallium arsenide (GaAs), indium arsenide (InAs), and indium phosphide (InP). In some embodiments, the substrate 110 may have a silicon-on-insulator (SOI) structure. For example, the substrate 110 may include a buried oxide layer (BOX). For example, the substrate 110 may include an impurity-doped well or an impurity-doped structure.

For example, the isolation film 116 and the peripheral isolation film 115 may include a material including at least one selected from a group consisting of silicon oxide, silicon nitride, and silicon oxynitride. The isolation film 116 may be constituted of a single layer including one type of insulating film, a double layer including two types of insulating films, or a multi-layer including at least three types of insulating films. For example, the isolation film 116 may be constituted of a double or multi-layer including an oxide film and a nitride film. However, the composition of the isolation film 116 is not limited to the description above. A plurality of active regions 118 may be defined by the isolation film 116 in the substrate 110 in the memory cell region CR (in FIG. 2). A plurality of peripheral active regions 117 may be defined by the peripheral isolation film 115 in the substrate 110 in the peripheral region PR (in FIG. 2).

In some embodiments, the isolation film 116 and the peripheral isolation film 115 may be formed together and referred to as an isolation structure together. The isolation film 116 may correspond to a portion of the isolation structure, which defines the active regions 118, and the peripheral isolation film 115 may correspond to a portion of the isolation structure, which defines the peripheral active regions 117. The isolation film 116 and the peripheral isolation film 115 may not be clearly distinguished from each other at the boundary between the memory cell region CR and the peripheral region PR.

Like the active regions ACT in FIG. 2, each of the active regions 118 may have a relatively long island shape, which has a short axis and a long axis in a plan view. Like the peripheral active region ACTP in FIG. 2, each of the peripheral active regions 117 may have a rectangular shape in a plan view, but this is just an example. Embodiments are not limited thereto, and each of the peripheral active regions 117 may have various shapes in a plan view.

A plurality of word line trenches 120T may be formed in the substrate 110. The word line trenches 120T may extend in the first horizontal direction (the X direction) to be parallel with each other, cross the active regions 118, and may be arranged at regular intervals in the second horizontal direction (the Y direction). Each of the word line trenches 120T may have a line shape. In some embodiments, a step may be formed in the bottom surface of each of the word line trenches 120T.

After a resultant structure with the word line trenches 120T is cleaned, a gate dielectric film 122, a word line 120, and a buried insulating film 124 may be sequentially formed in each of the word line trenches 120T. A plurality of word lines 120 may respectively form the word lines WL in FIG. 2. The word lines 120 may extend in the first horizontal direction (the X direction) to be parallel with each other, cross the active regions 118, and may be arranged at regular intervals in the second horizontal direction (the Y direction). Each of the word lines 120 may have a line shape. The top surface of each of the word lines 120 may be at a lower vertical level (e.g., in the Z direction) than the top surface of the substrate 110. The bottom surfaces of the word lines 120 may have a rugged shape, and a transistor having a saddle fin structure, e.g., a saddle fin field-effect transistor (FinFET), may be formed in the active regions 118.

The term “level” or “vertical level” used herein refers to a height from the main surface or the top surface of the substrate 110 in a vertical direction (the Z direction). In other words, “being at the same level” or “being at a certain level” refers to “having the same height from the main surface of the substrate 110 in the vertical direction (the Z direction)” or “being at a certain position”, and “being at a low/high level” refers to “being at a low/high position with respect to the main surface of the substrate 110 in the vertical direction (the Z direction)”.

Each of the word lines 120 may have a stack structure, in which a lower word line layer 120a and an upper word line layer 120b are stacked. For example, the lower word line layer 120a may include a metal material, a conductive metal nitride, or a combination thereof. In some embodiments, the lower word line layer 120a may include Ti, TiN, Ta, TaN, W, WN, TiSiN, WSiN, or a combination thereof. For example, the lower word line layer 120a may include doped polysilicon. In some embodiments, the lower word line layer 120a may include a core layer and a barrier layer between the core layer and the gate dielectric film 122.

In some embodiments, before or after the word lines 120 are formed, impurity ions may be implanted into active regions 118 of the substrate 110, which are respectively at both sides of each of the word lines 120, thereby forming a source region and a drain region in the active regions 118.

The gate dielectric film 122 may include at least one selected from a group consisting of a silicon oxide film, a silicon nitride film, a silicon oxynitride film, oxide/nitride/oxide (ONO), and a high-k dielectric film having a higher dielectric constant than the silicon oxide film. For example, the gate dielectric film 122 may have a dielectric constant of about 10 to about 25.

The top surfaces of a plurality of buried insulating films 124 may be substantially at the same vertical level as the top surface of the substrate 110. The buried insulating films 124 may include at least one material selected from a group consisting of silicon oxide, silicon nitride, silicon oxynitride, and a combination thereof.

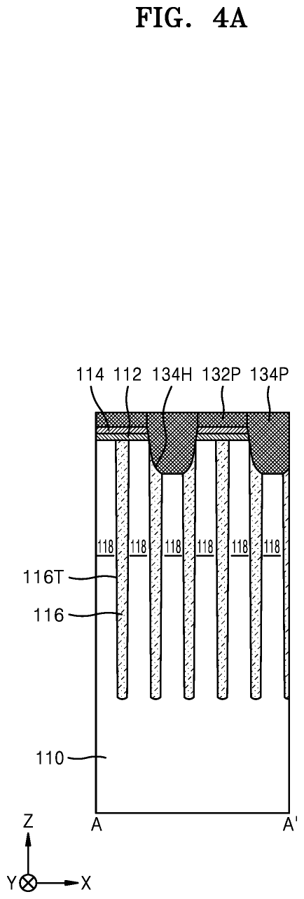

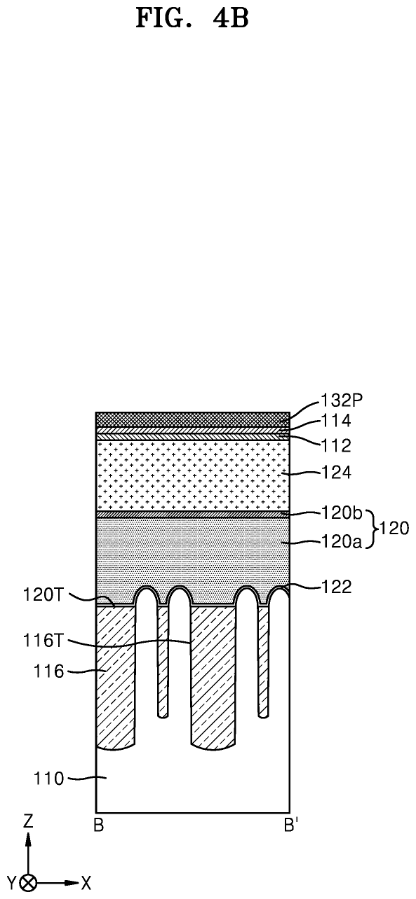

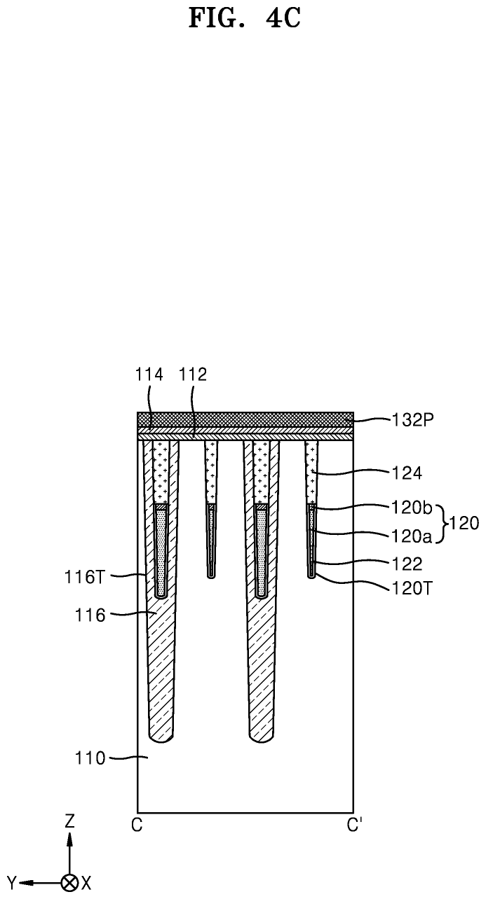

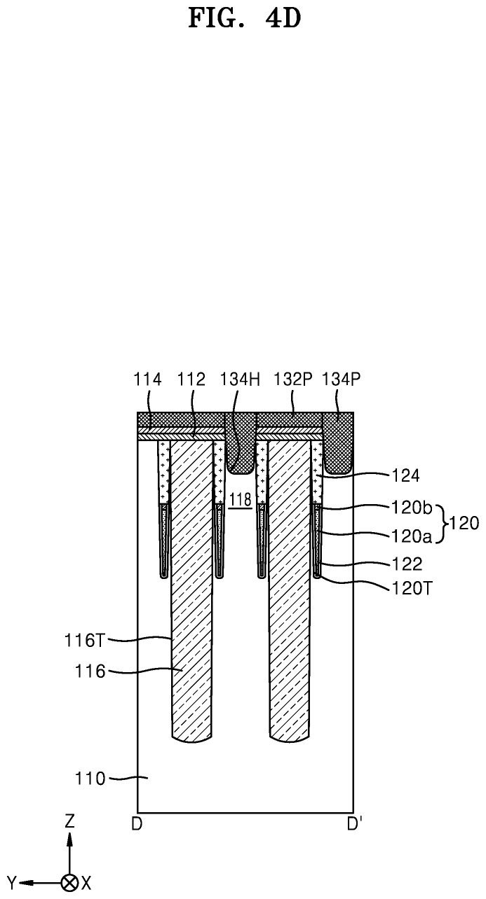

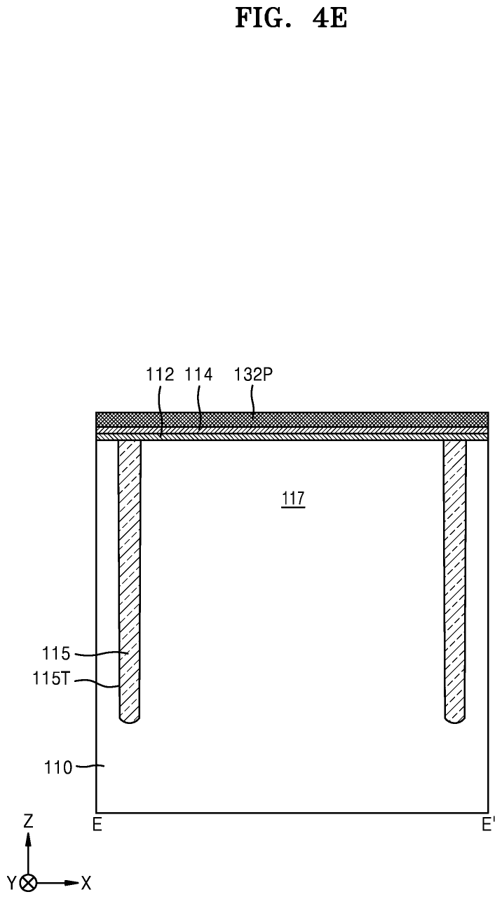

Referring to FIGS. 4A to 4E, an insulating film pattern may be formed to cover the isolation film 116, the active regions 118, the buried insulating films 124, the peripheral isolation film 115, and the peripheral active regions 117. For example, the insulating film pattern may include silicon oxide, silicon nitride, silicon oxynitride, a metal dielectric, or a combination thereof. In some embodiments, the insulating film pattern may be constituted of a plurality of insulating films including a first insulating film pattern 112 and a second insulating film pattern 114. In some embodiments, the first insulating film pattern 112 may include silicon oxide, and the second insulating film pattern 114 may include silicon oxynitride. In some embodiments, the first insulating film pattern 112 may include a nonmetal dielectric, and the second insulating film pattern 114 may include a metal dielectric.

A conductive semiconductor layer 132P may be formed on the first and second insulating film patterns 112 and 114. Thereafter, a direct contact hole 134H may be formed to pass through the conductive semiconductor layer 132P and the first and second insulating film patterns 112 and 114 and expose a source region in an active region 118, and a direct contact conductive layer 134P may be formed to fill the direct contact hole 134H. In some embodiments, the direct contact hole 134H may extend inside the active region 118, i.e., the source region. For example, the conductive semiconductor layer 132P may include doped polysilicon. For example, the direct contact conductive layer 134P may include doped polysilicon. In some embodiments, the direct contact conductive layer 134P may include an epitaxial silicon layer.

Referring to FIGS. 5A to 5E, a metal conductive layer and an insulating capping layer may be formed to cover the conductive semiconductor layer 132P and the direct contact conductive layer 134P. In some embodiments, the metal conductive layer may have a stack structure, in which a first metal conductive layer and a second metal conductive layer are stacked. A plurality of bit lines 147 and a plurality of insulating capping lines 148 may be formed by etching the first metal conductive layer, the second metal conductive layer, and the insulating capping layer. Each of the bit lines 147 has a stack structure of a first metal conductive pattern 145 and a second metal conductive pattern 146, which have a line shape.

In some embodiments, the first metal conductive pattern 145 may include titanium nitride (TiN) or Ti—Si—N (TSN). The second metal conductive pattern 146 may include tungsten (W) or W and tungsten silicide (WSiₓ). In some embodiments, the first metal conductive pattern 145 may function as a diffusion barrier. In some embodiments, the insulating capping lines 148 may include silicon nitride.

An insulating spacer structure 150 may be formed on each of opposite side walls of a stack structure of a bit line 147 and an insulating capping line 148. The insulating spacer structure 150 may cover each of opposite side walls of the bit line 147 and each of opposite side walls of the insulating capping line 148. The insulating spacer structure 150 may include a first insulating spacer 152, a second insulating spacer 154, and a third insulating spacer 156. The second insulating spacer 154 may include a material that has a lower permittivity than the first insulating spacer 152 and the third insulating spacer 156. In some embodiments, the first insulating spacer 152 and the third insulating spacer 156 may include nitride, and the second insulating spacer 154 may include oxide. In some embodiments, the first insulating spacer 152 and the third insulating spacer 156 may include nitride, and the second insulating spacer 154 may include a material that has an etch selectivity with respect to the first insulating spacer 152 and the third insulating spacer 156. For example, when the first insulating spacer 152 and the third insulating spacer 156 include nitride, the second insulating spacer 154 may include oxide and may be removed during a subsequent process to be an air spacer that is defined by the first insulating spacer 152 and the third insulating spacer 156.

One bit line 147, one insulating capping line 148 covering the bit line 147, and a pair of insulating spacer structures 150 respectively covering opposite sides of the stack structure of the bit line 147 and the insulating capping line 148 may form a bit line structure 140. A plurality of bit line structures 140, each of which includes the bit line 147, the insulating capping line 148 covering the bit line 147, and the insulating spacer structures 150 respectively covering the opposite sides of the bit line 147 and the insulating capping line 148, may extend in the second horizontal direction (the Y direction) that is parallel with the main surface of the substrate 110 and may be parallel with each other. A plurality of bit lines 147 may respectively form the bit lines BL in FIG. 2. In some embodiments, the bit line structure 140 may further include a conductive semiconductor pattern 132 corresponding to a portion of the conductive semiconductor layer 132P (in FIGS. 4A and 4D) between the insulating film pattern (including the first and second insulating film patterns 112 and 114) and the first metal conductive pattern 145. For example, the bit line structure 140 may include the conductive semiconductor pattern 132, the bit line 147 having a stack structure of the first metal conductive pattern 145 and the second metal conductive pattern 146, the insulating capping line 148, and a pair of insulating spacer structures 150.

During an etching process of forming the bit lines 147, portions of the conductive semiconductor layer 132P (in FIGS. 4A to 4E) and portions of the direct contact conductive layer 134P (in FIGS. 4A and 4D), which do not vertically overlap with the bit lines 147, may also be etched, thereby forming a plurality of conductive semiconductor patterns 132 and a plurality of direct contact conductive patterns 134. At this time, the insulating film pattern (including the first and second insulating film patterns 112 and 114) may function as an etch stop layer during the etching process of forming the bit lines 147, the conductive semiconductor patterns 132, and the direct contact conductive patterns 134. The direct contact conductive patterns 134 may form the direct contacts DC illustrated in FIG. 2. The bit lines 147 may be electrically connected to the active regions 118 through the direct contact conductive patterns 134.

A plurality of buried contact holes 170H may be formed among the bit line structures 140. The inner space of each of the buried contact holes 170H may be between two adjacent bit lines 147 and defined by an active region 118 therebetween and insulating spacer structures 150 covering respective side walls of the two adjacent bit lines 147.

The buried contact holes 170H may be formed by partially removing the insulating film pattern (including the first and second insulating film patterns 112 and 114) and the active regions 118 by using the insulating spacer structures 150, which cover the side walls of the bit lines 147 and the side walls of the insulating capping lines 148, as etch masks. In some embodiments, the buried contact holes 170H may be formed by performing an anisotropic etching process of partially removing the insulating film pattern (including the first and second insulating film patterns 112 and 114) and the active regions 118 by using, as etch masks, the insulating spacer structures 150 covering the side walls of the insulating capping lines 148 and the side walls of the bit lines 147 and then performing an isotropic etching process of further removing a portion of each of the active regions 118 such that the space of each of the buried contact holes 170H, which is defined by an active region 118, may be extended.

A gate line structure 140P may be formed on a peripheral active region 117. The gate line structure 140P may include a gate line 147P, an insulating capping line 148 covering the gate line 147P, and a gate insulating spacer 150P covering respective side walls of the gate line 147P and the insulating capping line 148. The gate line 147P of the gate line structure 140P may be formed together with the bit lines 147. For example, the gate line 147P may have a stack structure of the first metal conductive pattern 145 and the second metal conductive pattern 146. A gate insulating film pattern 142 may be between the gate line 147P and the peripheral active region 117. In some embodiments, the gate line structure 140P may further include a conductive semiconductor pattern 132 between the gate insulating film pattern 142 and the first metal conductive pattern 145. A plurality of gate lines 147P may form the gate line patterns GLP in FIG. 2.

For example, the gate insulating spacer 150P may include nitride. In some embodiments, the gate insulating spacer 150P may be constituted of a single layer but is not limited thereto. The gate insulating spacer 150P may have a stack structure of at least two layers. In some embodiments, the gate insulating spacer 150P may be formed together with the insulating spacer structures 150 and, like the insulating spacer structures 150, may include the first insulating spacer 152, the second insulating spacer 154, and the third insulating spacer 156.

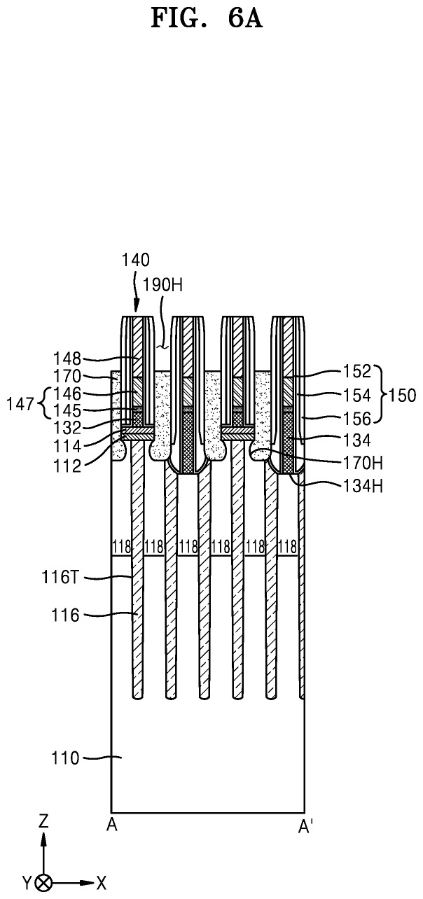

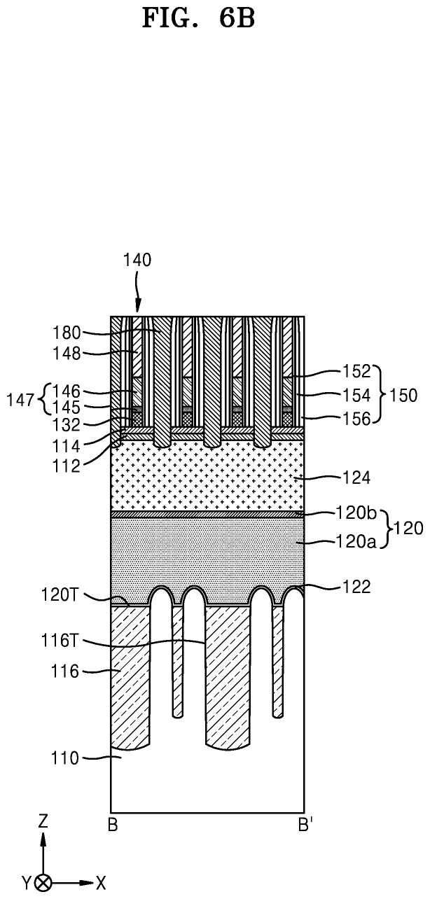

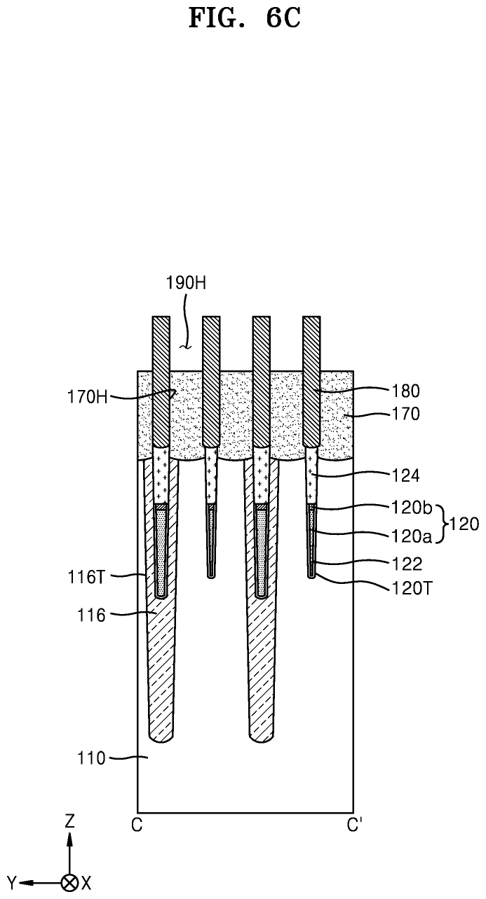

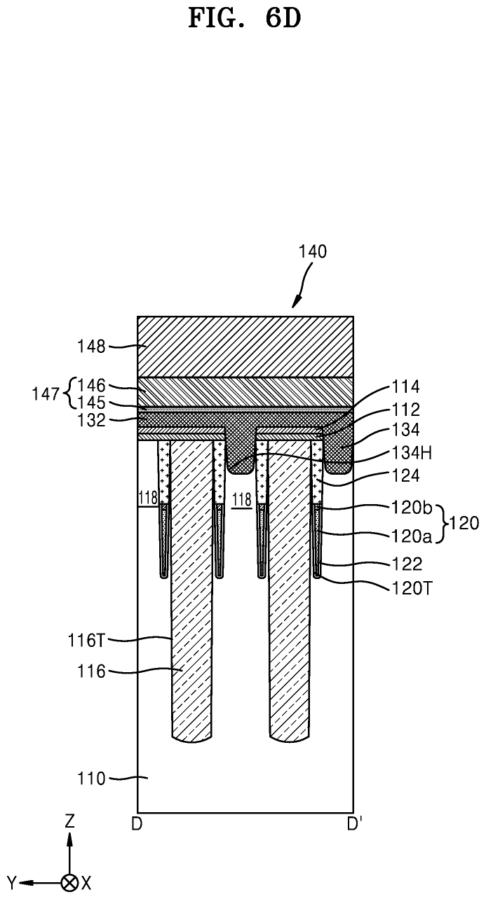

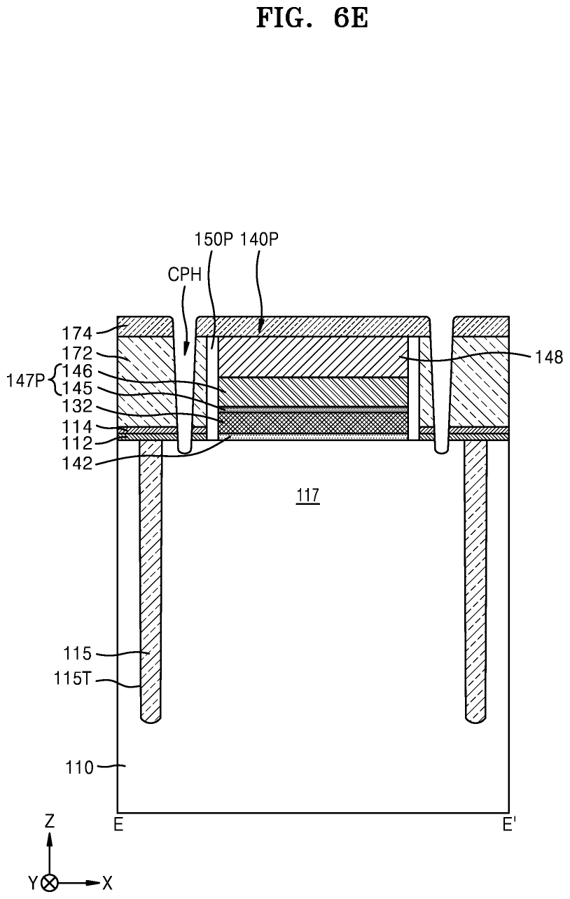

Referring to FIGS. 6A to 6E, a plurality of buried contacts 170 and a plurality of insulating fences 180 may be formed in spaces among the bit line structures 140. The buried contacts 170 and the insulating fences 180 may be alternately arranged between two adjacent insulating spacer structures 150 among the insulating spacer structures 150, which cover the side walls of the insulating capping lines 148 and the side walls of the bit lines 147, in the second horizontal direction (e.g., the Y direction). For example, the buried contacts 170 may include polysilicon. For example, the insulating fences 180 may include nitride.

In some embodiments, the buried contacts 170 may be arranged in lines in the first horizontal direction (the X direction) and the second horizontal direction (the Y direction). Each of the buried contacts 170 may extend from an active region 118 in the vertical direction (the Z direction) perpendicular to the substrate 110. The buried contacts 170 may form the buried contacts BC illustrated in FIG. 2.

The buried contacts 170 may be arranged in spaces defined by the insulating fences 180 and the insulating spacer structures 150 covering the side walls of the insulating capping lines 148 and the side walls of the bit lines 147. The buried contacts 170 may respectively fill the buried contact holes 170H in a lower portion of the space among the bit line structures 140.

The vertical level of the top surface of each of the buried contacts 170 may be lower than the vertical level of the top surface of each of the insulating capping lines 148, i.e., the vertical level of the topmost surface of each of the bit line structures 140. The top surface of each of the insulating fences 180 may be at the same level as the top surface of each of the insulating capping lines 148 in the vertical direction (the Z direction). In some embodiments, the vertical level of the top surface of each of the buried contacts 170 may be higher than the vertical level of the top surface of each of the bit lines 147.

A plurality of first landing pad holes 190H may be defined by the insulating spacer structures 150 covering the side walls of the insulating capping lines 148 and the side walls of the bit lines 147, the insulating fences 180, and the buried contacts 170. The buried contacts 170 may be respectively exposed at the bottoms of the first landing pad holes 190H.

A first filling insulation layer 172 may be formed on the insulating film pattern (including the first and second insulating film patterns 112 and 114) around the gate line structure 140P, and a second filling insulation layer 174 may be formed on the first filling insulation layer 172 and the insulating capping line 148. In some embodiments, the first filling insulation layer 172 may be formed such that the top surface of the first filling insulation layer 172 is at the same vertical level as the top surface of the gate line structure 140P, i.e., the top surface of the insulating capping line 148 of the gate line structure 140P. For example, the second filling insulation layer 174 may be formed to cover the insulating capping line 148 of the gate line structure 140P and the first filling insulation layer 172. In some embodiments, the first filling insulation layer 172 may include oxide, and the second filling insulation layer 174 may include nitride.

In a process of forming the buried contacts 170 and/or the insulating fences 180, an upper portion of each of the insulating capping lines 148 and the insulating spacer structures 150 of the bit line structures 140 and an upper portion of each of the insulating capping line 148 and the gate insulating spacer 150P of the gate line structure 140P may be removed such that the vertical level of the top surface of each of the bit line structures 140 and the gate line structure 140P may be lowered.

Thereafter, a plurality of contact holes CPH may be formed to pass through the second filling insulation layer 174, the first filling insulation layer 172, and the insulating film pattern (including the first and second insulating film patterns 112 and 114). Each of the contact holes CPH may extend to the peripheral active region 117 through the second filling insulation layer 174, the first filling insulation layer 172, and the insulating film pattern (including the first and second insulating film patterns 112 and 114). In some embodiments, the contact holes CPH may extend inside the peripheral active region 117.

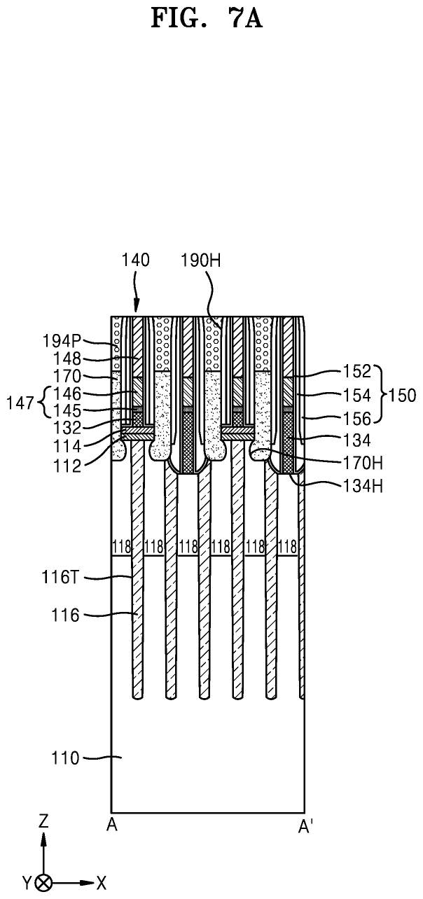

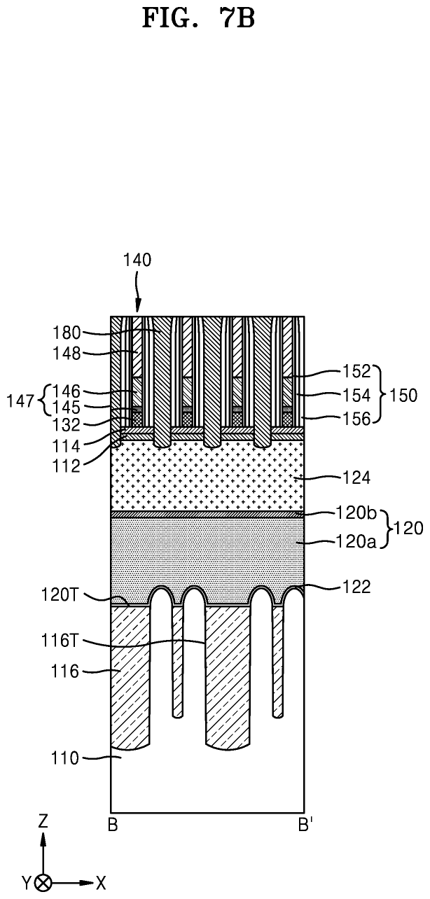

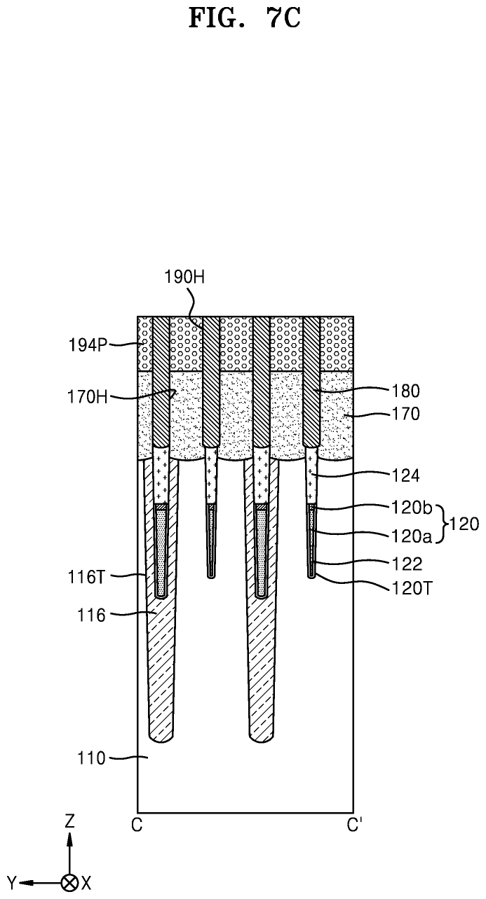

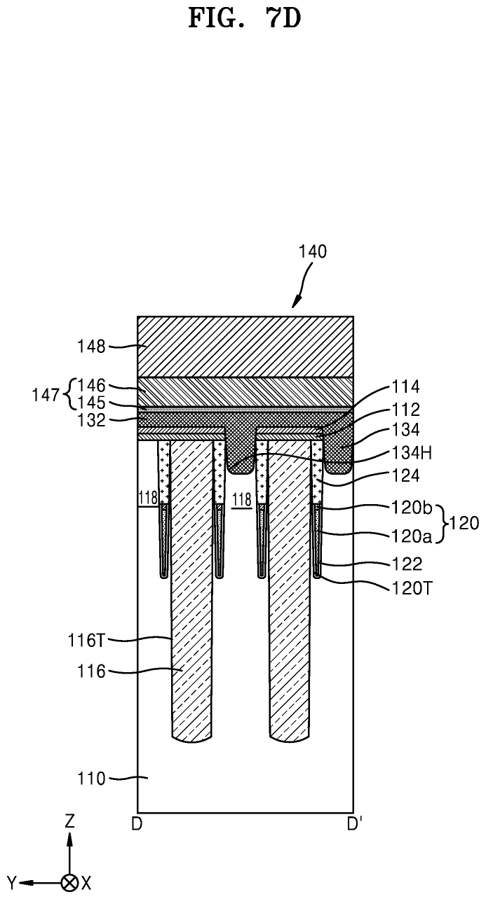

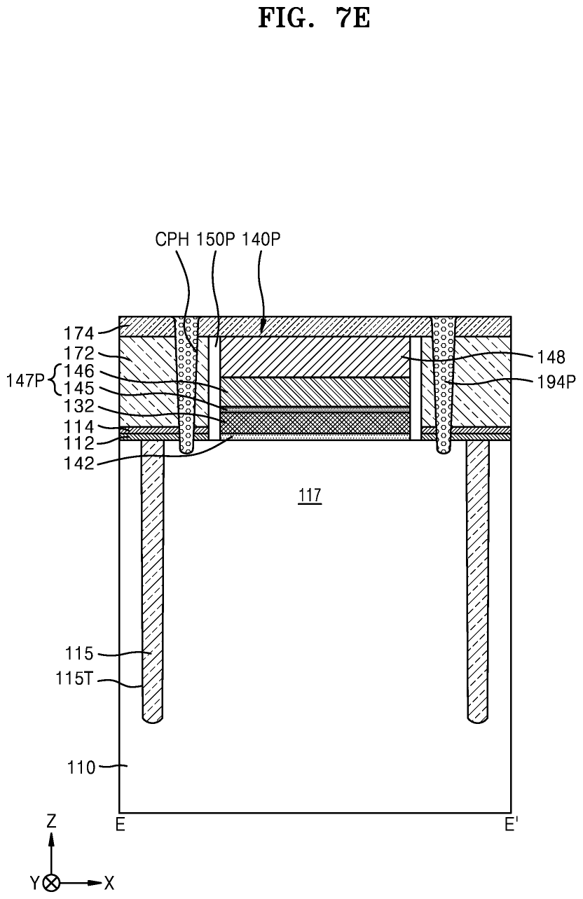

Referring to FIGS. 7A to 7E, a first preliminary conductive material layer 194P may be formed to fill the first landing pad holes 190H and the contact holes CPH. The first preliminary conductive material layer 194P may be formed by forming a first material layer, which fills the first landing pad holes 190H and the contact holes CPH and covers the bit line structures 140, the insulating fences 180, and the second filling insulation layer 174, and removing an upper portion of the first material layer to expose the bit line structures 140, the insulating fences 180, and the second filling insulation layer 174.

For example, the first preliminary conductive material layer 194P may include tungsten (W). In some embodiments, before the first material layer is formed, a metal silicide film may be formed on the buried contacts 170 and the peripheral active region 117. The metal silicide film may be between each of the buried contacts 170 and the first preliminary conductive material layer 194P and between the peripheral active region 117 and the first preliminary conductive material layer 194P. The metal silicide film may include cobalt silicide (CoSiₓ), nickel silicide (NiSiₓ), or manganese silicide (MnSiₓ) but is not limited thereto.

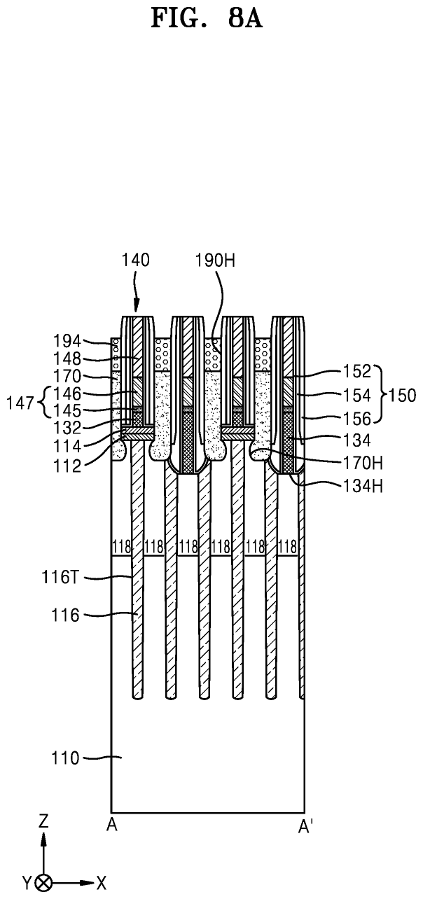

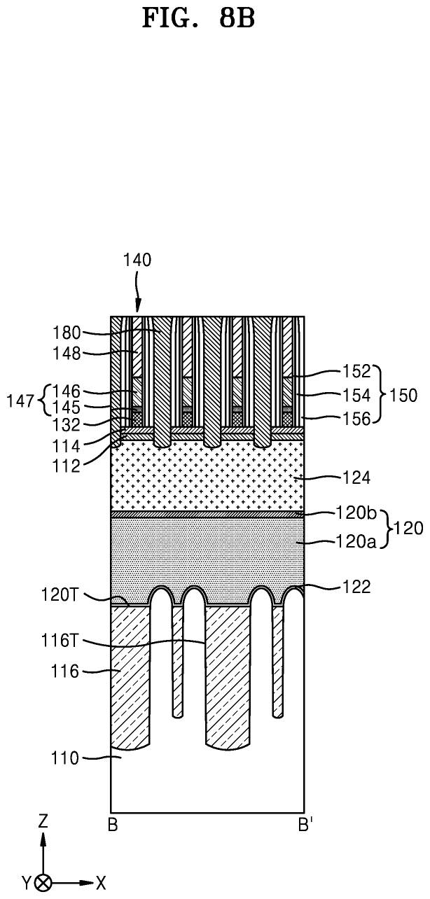

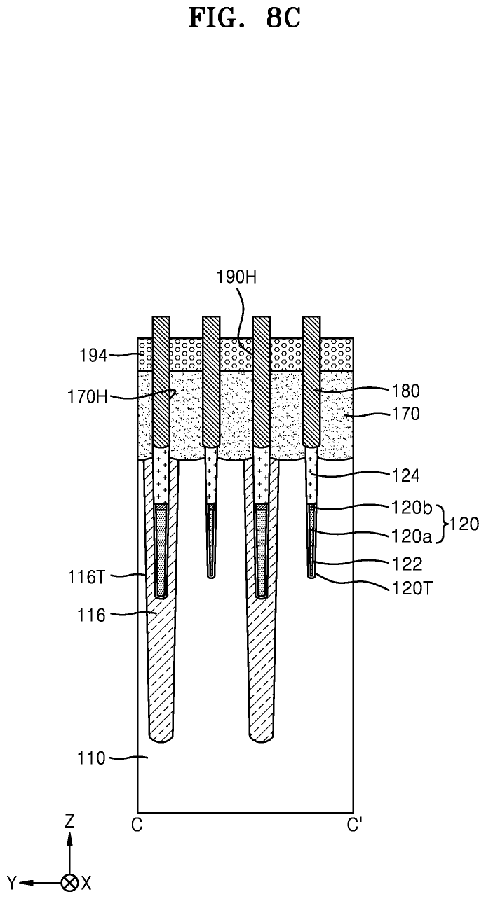

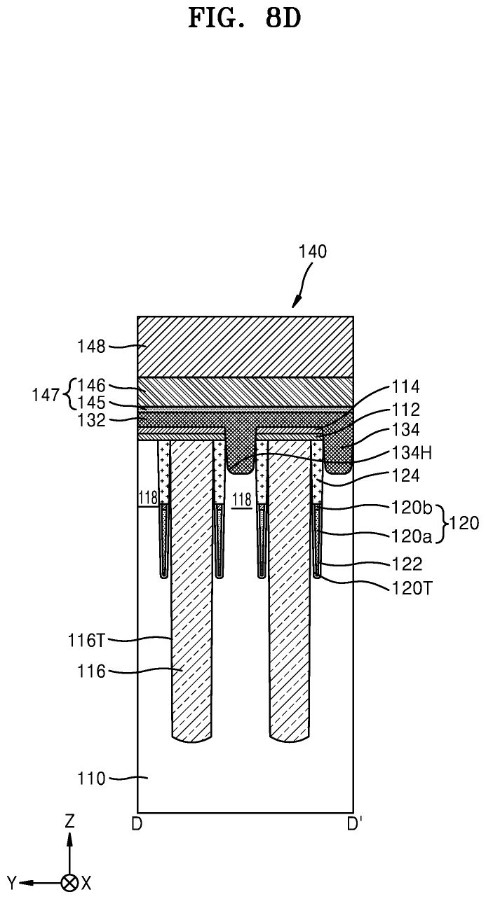

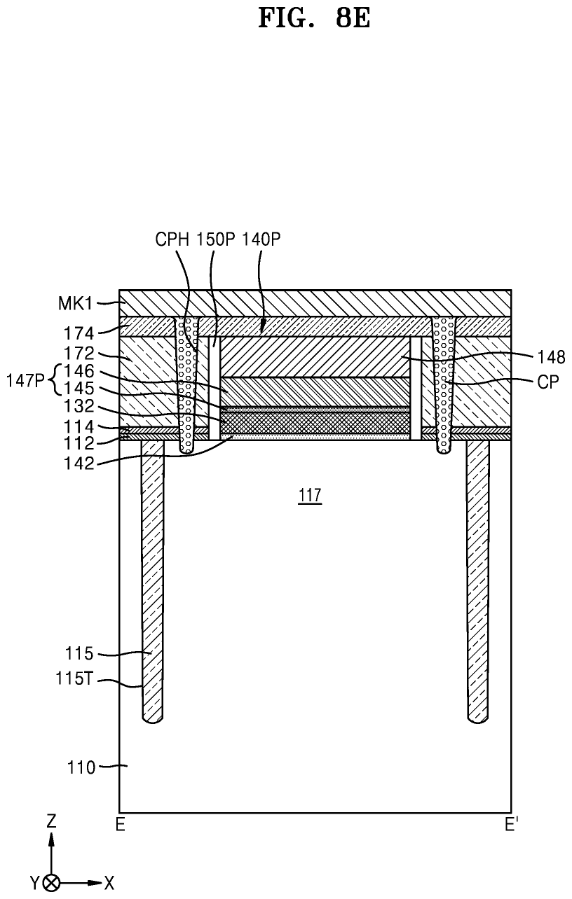

Referring to FIGS. 7A to 8E, a first mask pattern MK1 (not illustrated) may be formed to cover the peripheral region PR (in FIG. 2). The first mask pattern MK1 may not cover the memory cell region CR (in FIG. 2). After the first mask pattern MK1 is formed, a plurality of lower landing pads 194 may be formed by removing an upper portion of the first preliminary conductive material layer 194P. For example, the lower landing pads 194 may be formed by removing a portion of the first preliminary conductive material layer 194P, which fills respective upper portions of the first landing pad holes 190H. In some embodiments, the top surface of each of the lower landing pads 194 may be at a higher vertical level than the top surface of each of the bit lines 147, i.e., the top surface of each of the second metal conductive patterns 146.

In a process of forming the lower landing pads 194, the first preliminary conductive material layer 194P filling the contact holes CPH is covered with the first mask pattern MK1 and may thus not removed. The first preliminary conductive material layer 194P filling the contact holes CPH may form a plurality of contact plugs CP. The contact plugs CP may respectively fill the contact holes CPH and may be electrically connected to the peripheral active region 117. In some embodiments, the metal silicide film may be between the contact plugs CP and the peripheral active region 117.

After the lower landing pads 194 and the contact plugs CP are formed, the first mask pattern MK1 may be removed.

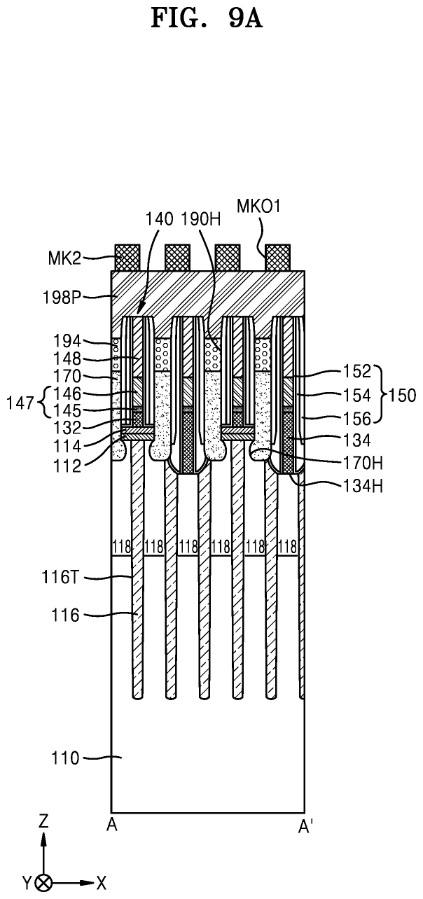

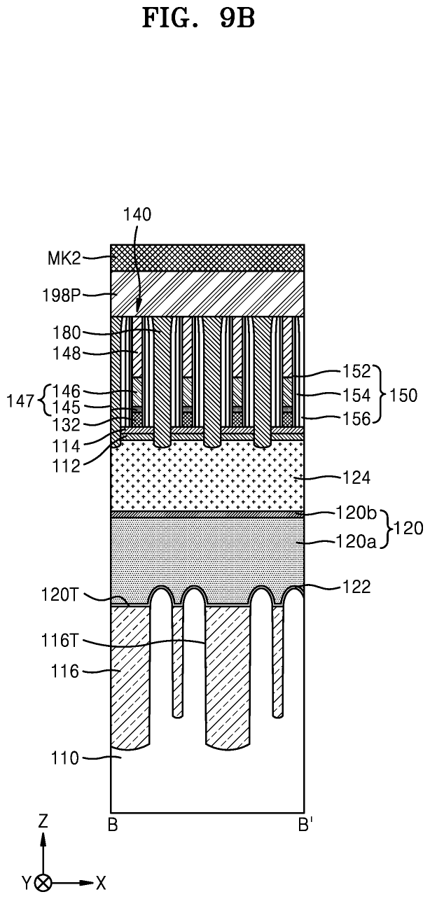

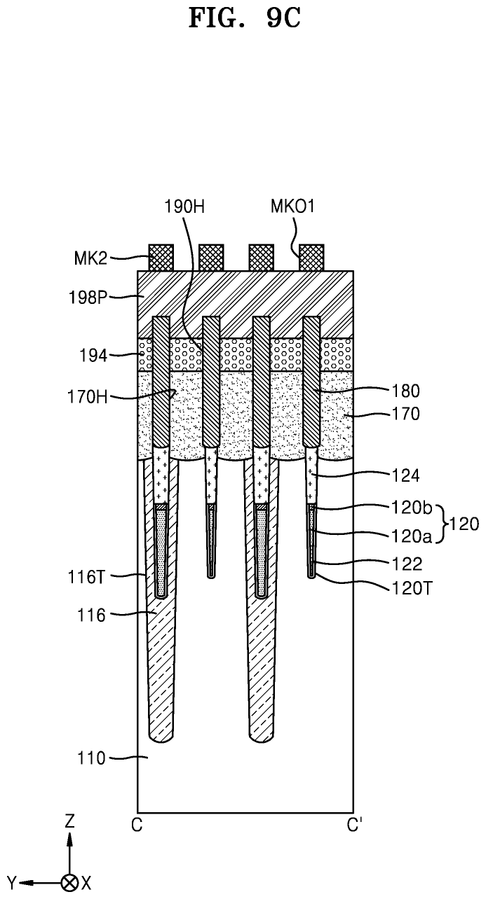

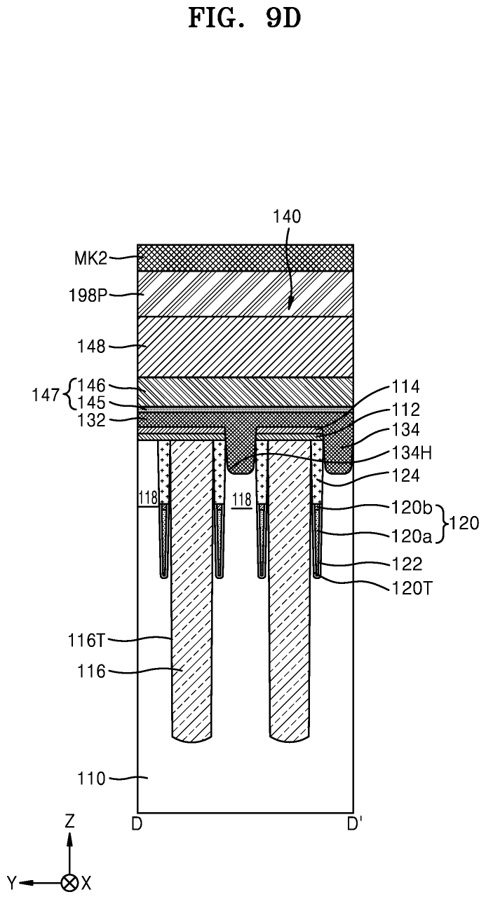

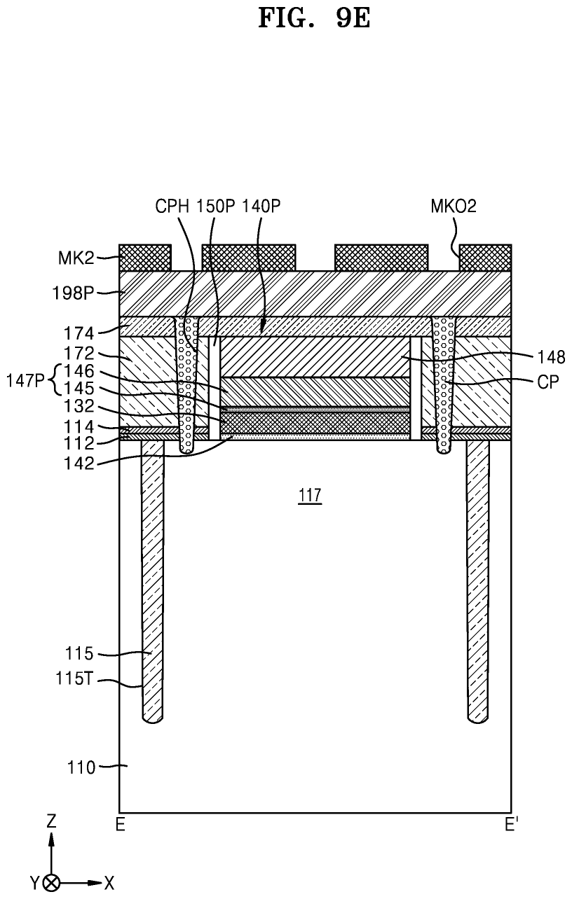

Referring to FIGS. 9A to 9E, a preliminary insulating material layer 198P may be formed to fill an upper portion of each of the first landing pad holes 190H and cover the bit line structures 140, the insulating fences 180, and the second filling insulation layer 174. The preliminary insulating material layer 198P may include nitride. For example, the preliminary insulating material layer 198P may include silicon nitride. In some embodiments, the preliminary insulating material layer 198P may include an interlayer insulating layer and an etch stop layer covering the interlayer insulating layer. For example, the interlayer insulating layer may include oxide, and the etch stop layer may include nitride.

A second mask pattern MK2 may be formed on the preliminary insulating material layer 198P. The second mask pattern MK2 may have a plurality of first mask openings MKO1 and a plurality of second mask openings MKO2. The first mask openings MKO1 may be in the memory cell region CR (in FIG. 2), and the second mask openings MKO2 may be in the peripheral region PR (in FIG. 2).

Each of the first mask openings MKO1 may overlap in the vertical direction (the Z direction) with at least a portion of a first landing pad hole 190H and at least a portion of a lower landing pad 194 filling the first landing pad hole 190H. In some embodiments, each of the first mask openings MKO1 may overlap in the vertical direction (the Z direction) with a portion of the first landing pad hole 190H, a portion of the lower landing pad 194 filling the first landing pad hole 190H, and a portion of a bit line structure 140.

At least some of the second mask openings MKO2 may respectively overlap in the vertical direction (the Z direction) with the contact holes CPH and the contact plugs CP, which respectively fill the contact holes CPH. In some embodiments, the contact holes CPH and the contact plugs CP filling the contact holes CPH may completely overlap with some of the second mask openings MKO2, respectively, in the vertical direction.

The second mask pattern MK2 may be formed by extreme ultraviolet (EUV) lithography. For example, a portion of the second mask pattern MK2, which has the first mask openings MKO1 and is in the memory cell region CR, and a portion of the second mask pattern MK2, which has the second mask openings MKO2 and is in the peripheral region PR, may be formed by EUV lithography using a single EUV mask. For example, to form the second mask pattern MK2, EUV lithography may be performed using EUV light having a wavelength of 13.5 nm.

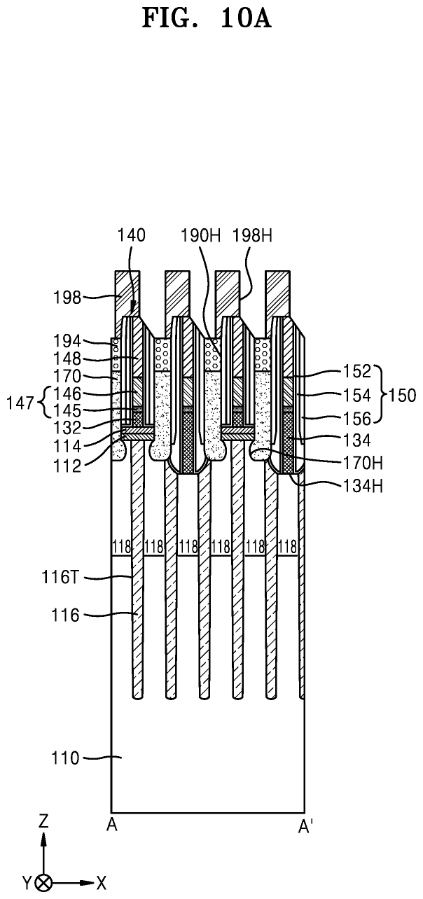

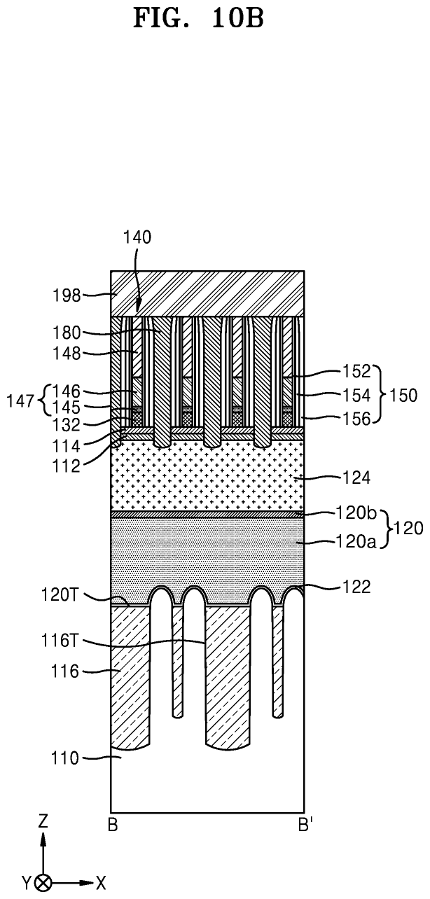

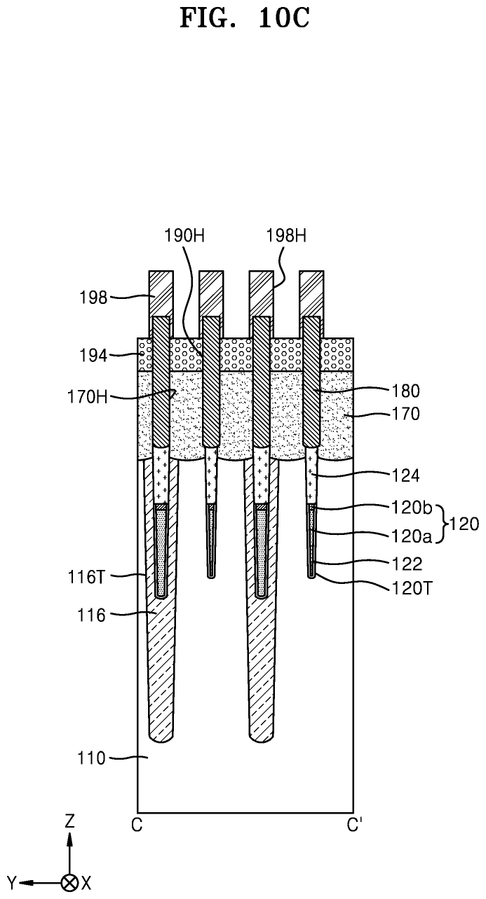

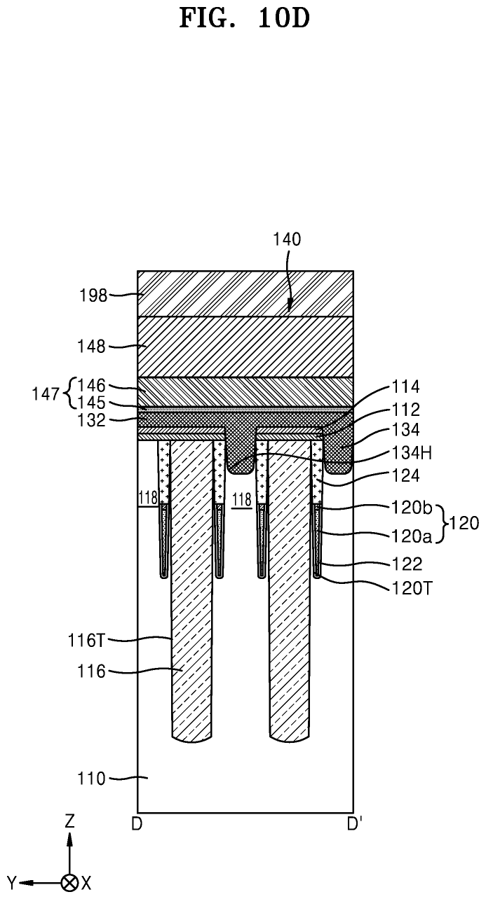

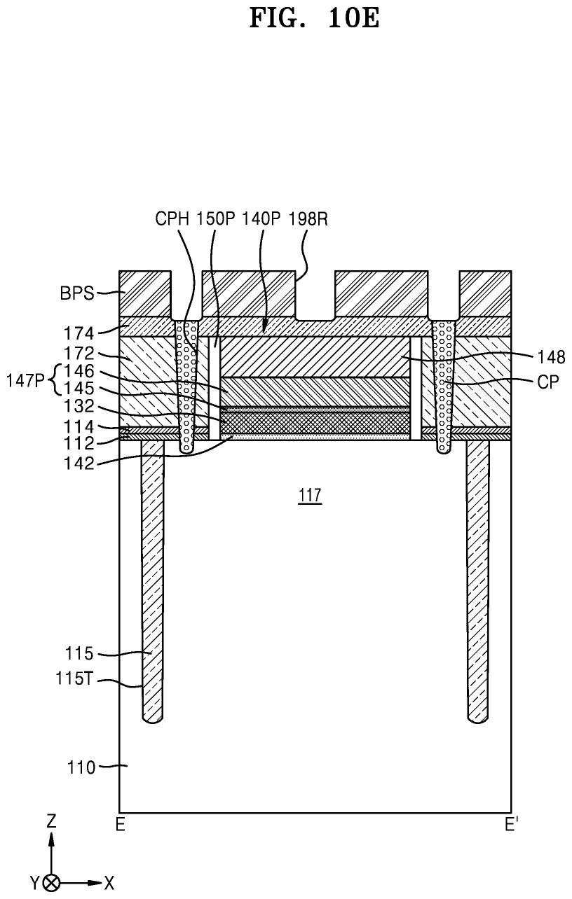

Referring to FIGS. 9A to 10E, a landing pad insulating structure 198 and a peripheral bit line insulating structure BPS may be respectively formed in the memory cell region CR (in FIG. 2) and the peripheral region PR (in FIG. 2) by patterning the preliminary insulating material layer 198P by using the second mask pattern MK2 as an etch mask. A portion of the preliminary insulating material layer 198P, which is patterned by using the second mask pattern MK2 in the memory cell region CR as an etch mask, becomes the landing pad insulating structure 198. A portion of the preliminary insulating material layer 198P, which is patterned by using the second mask pattern MK2 in the peripheral region PR as an etch mask, becomes the peripheral bit line insulating structure BPS.

The landing pad insulating structure 198 may have a plurality of second landing pad holes 198H respectively corresponding to the first mask openings MKO1. The peripheral bit line insulating structure BPS may have a plurality of peripheral bit line recesses 198R respectively corresponding to the second mask openings MKO2.

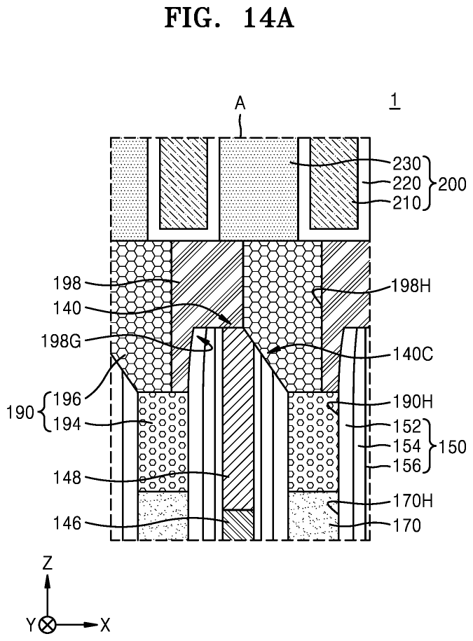

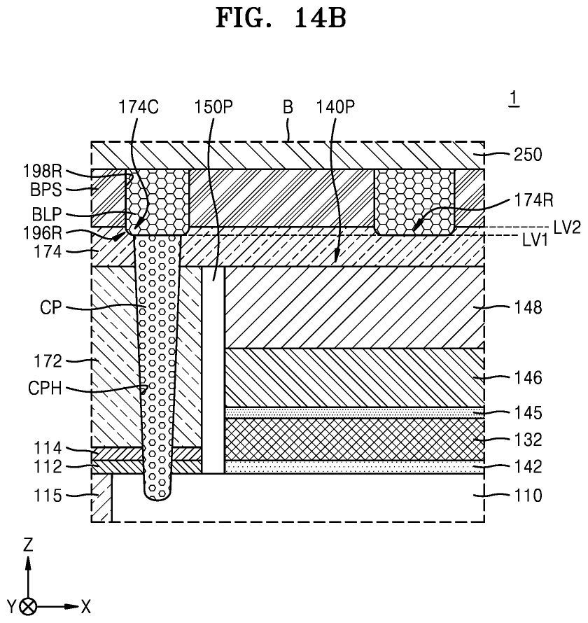

The second landing pad holes 198H may pass through the landing pad insulating structure 198 to be in communication with the first landing pad holes 190H, respectively. In a process of forming the second landing pad holes 198H, an upper portion of each of the bit line structures 140 may be removed. For example, in the process of forming the second landing pad holes 198H, an upper portion of each of the insulating spacer structures 150 and the insulating capping lines 148 of the bit line structures 140 may be removed, thereby forming a cut part 140C (in FIG. 14A). The cut part 140C may be formed in a portion of each of the bit line structures 140, which is not covered with the landing pad insulating structure 198. For example, opposite portions in the first horizontal direction (the X direction) of each of the bit line structures 140 may be asymmetrical with each other with respect to the second horizontal direction (the Y direction) in which each of the bit line structures 140 extends.

The landing pad insulating structure 198 may cover the top surface of each of the bit line structures 140 and extend along a side wall of each of the bit line structures 140, which does not have the cut part 140C, among opposite side walls in the second horizontal direction (the Y direction) of each of the bit line structures 140. In other words, each of the bit line structures 140 may extend in a lower portion of the landing pad insulating structure 198. In some embodiments, the bottommost surface of the landing pad insulating structure 198 may be in contact with each of the lower landing pads 194. For example, the landing pad insulating structure 198 may extend along the side wall of each of the bit line structures 140, which does not have the cut part 140C among the opposite side walls in the second horizontal direction (the Y direction) of each of the bit line structures 140, and may be in contact with each of the lower landing pads 194.

In some embodiments, an upper portion of each of the bit line structures 140, which is covered with the landing pad insulating structure 198, may have a round shape (not illustrated). An upper portion, i.e., the cut part 140C, of each of the bit line structures 140, which is not covered with the landing pad insulating structure 198, may have an oblique shape with a slope. The upper portion of each of the bit line structures 140 which is covered with the landing pad insulating structure 198, may be in contact with the landing pad insulating structure 198.

The peripheral bit line recesses 198R may pass through the peripheral bit line insulating structure BPS, and some of the peripheral bit line recesses 198R may respectively be in communication with the contact holes CPH. The contact plugs CP respectively filling the contact holes CPH and the second filling insulation layer 174 may be exposed by the bottom surfaces of the peripheral bit line recesses 198R. For example, the contact plugs CP may be exposed by portions of the bottom surfaces of the peripheral bit line recesses 198R, and the second filling insulation layer 174 may be exposed by the other portions of the bottom surfaces of the peripheral bit line recesses 198R. In some embodiments, the peripheral bit line recesses 198R may pass through the peripheral bit line insulating structure BPS and extend inside the second filling insulation layer 174. For example, the bottom surface of each of the peripheral bit line recesses 198R may be at a lower vertical level than the topmost surface of the second filling insulation layer 174. For example, the top surface of each of the contact plugs CP may be at a lower vertical level than the topmost surface of the second filling insulation layer 174. In some embodiments, the edge of the bottom surface of each of the peripheral bit line recesses 198R may have a round shape.

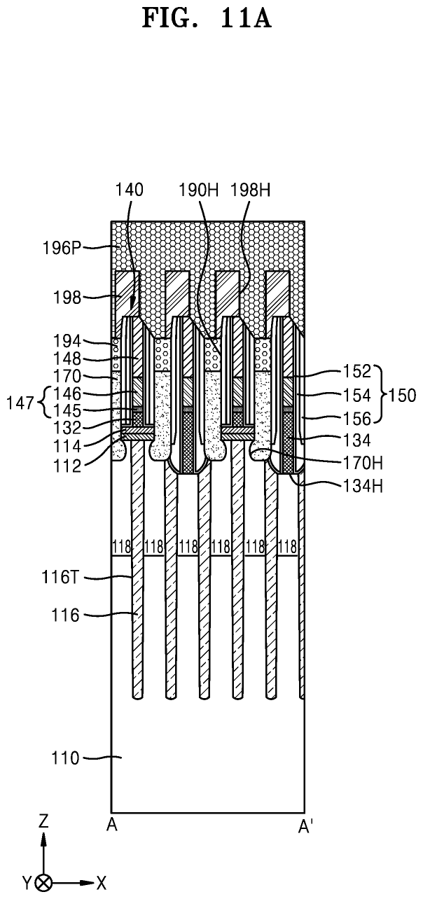

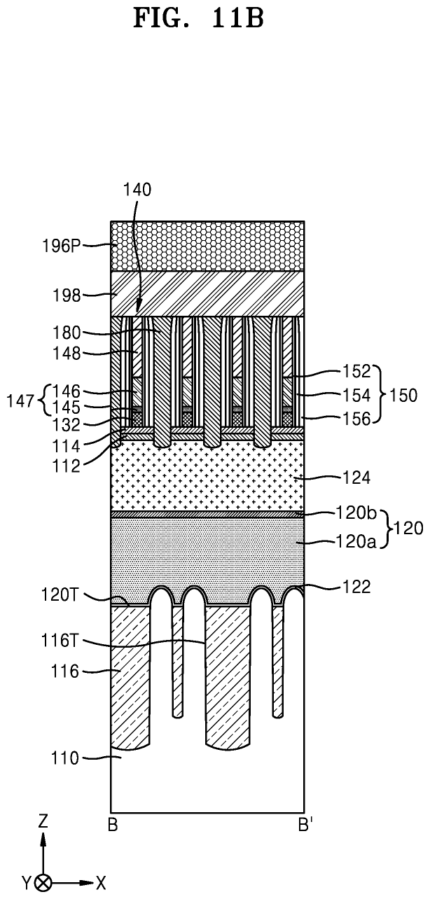

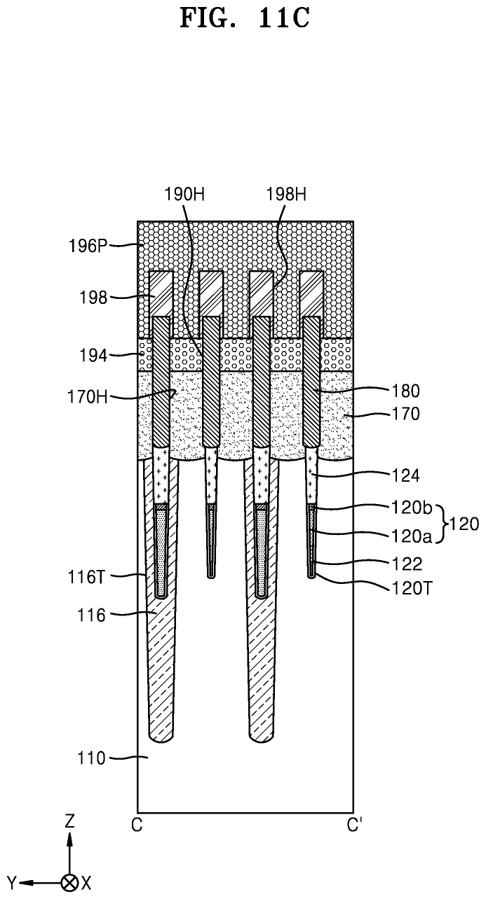

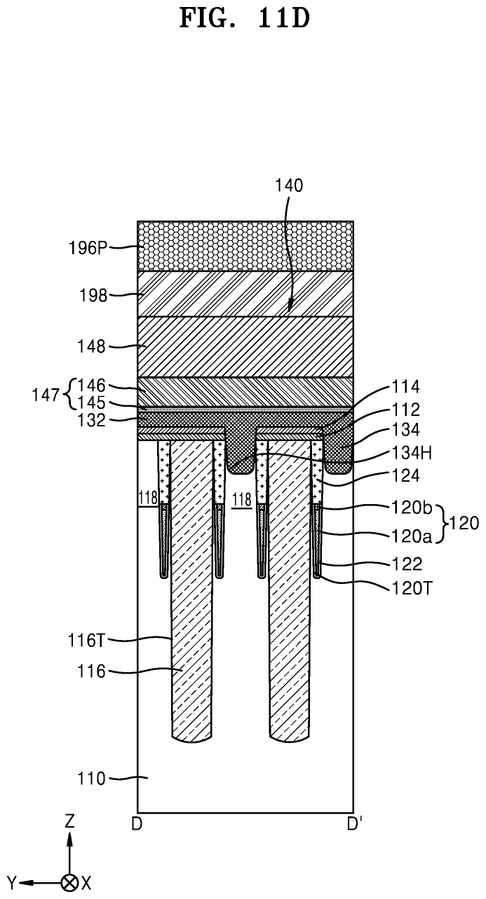

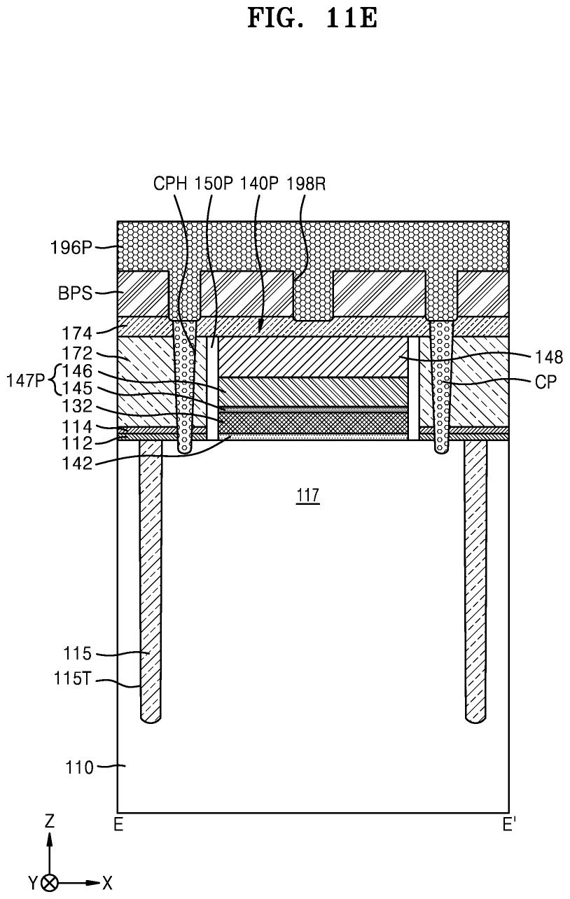

Referring to FIGS. 11A to 11E, a second preliminary conductive material layer 196P may be formed to fill the second landing pad holes 198H and the peripheral bit line recesses 198R and cover the landing pad insulating structure 198 and the peripheral bit line insulating structure BPS. The second preliminary conductive material layer 196P may include metal. For example, the second preliminary conductive material layer 196P may include tungsten (W). The second preliminary conductive material layer 196P may be in contact with the lower landing pads 194 and the contact plugs CP.

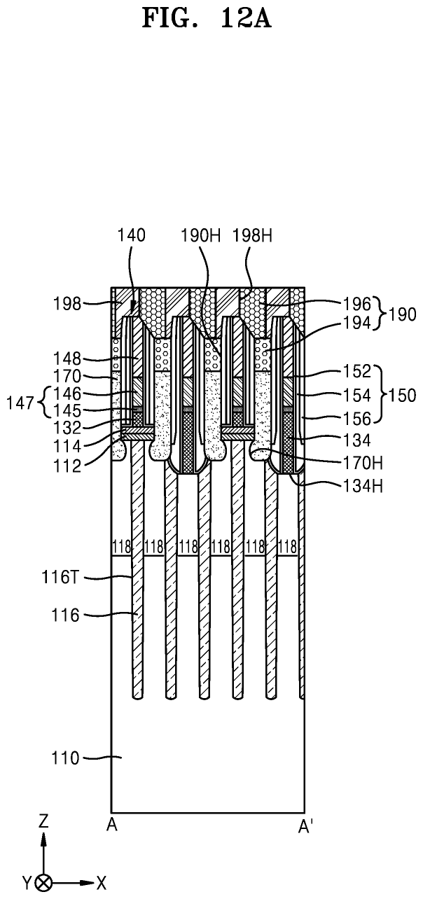

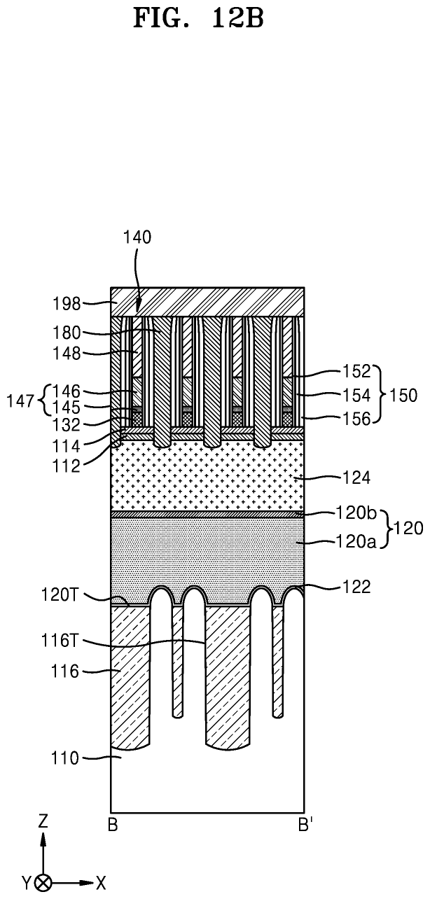

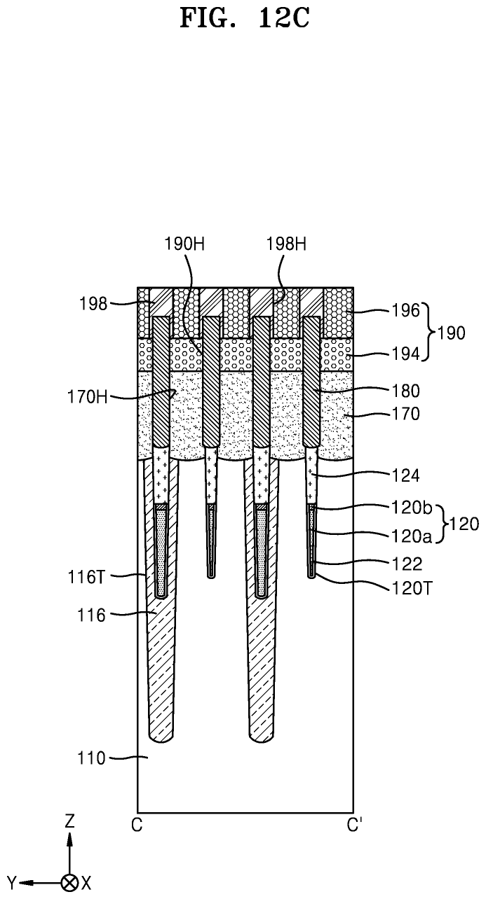

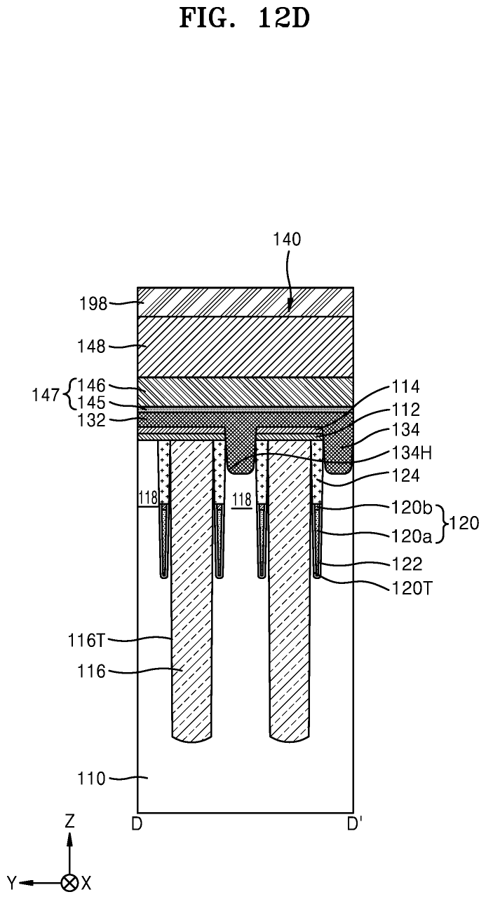

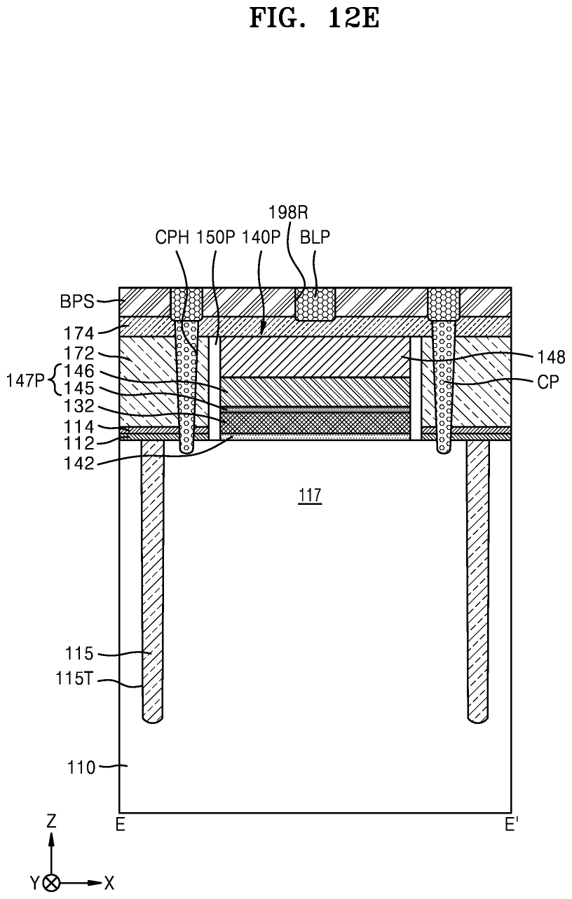

Referring to FIGS. 11A to 12E, a plurality of upper landing pads 196 respectively filling the second landing pad holes 198H and a plurality of peripheral bit lines BLP respectively filling the peripheral bit line recesses 198R may be formed by removing an upper portion of the second preliminary conductive material layer 196P to expose the landing pad insulating structure 198 and the peripheral bit line insulating structure BPS. The upper landing pads 196 may respectively correspond to portions of the second preliminary conductive material layer 196P, which respectively fill the second landing pad holes 198H. The peripheral bit lines BLP may respectively correspond to portions of the second preliminary conductive material layer 196P, which respectively fill the peripheral bit line recesses 198R. Chemical mechanical polishing (CMP) may be performed to remove an upper portion of the second preliminary conductive material layer 196P and expose the landing pad insulating structure 198 and the peripheral bit line insulating structure BPS, thereby forming the upper landing pads 196 and the peripheral bit lines BLP. For example, the top surface of each of the upper landing pads 196, the top surface of the landing pad insulating structure 198, the top surface of each of the peripheral bit lines BLP, and the top surface of the peripheral bit line insulating structure BPS may be at the same vertical level and coplanar with one another. Terms such as “same,” “equal,” “planar,” or “coplanar,” as used herein when referring to orientation, layout, location, shapes, sizes, compositions, amounts, or other measures do not necessarily mean an exactly identical orientation, layout, location, shape, size, composition, amount, or other measure, but are intended to encompass nearly identical orientation, layout, location, shapes, sizes, compositions, amounts, or other measures within acceptable variations that may occur, for example, due to manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

The upper landing pads 196 may respectively be in contact with the lower landing pads 194. The upper landing pads 196 and the lower landing pads 194 respectively corresponding thereto may form a plurality of landing pads 190. The landing pads 190 may be separated from each other by the landing pad insulating structure 198. The landing pads 190 may be respectively arranged on and electrically connected to the buried contacts 170. Each of the landing pads 190 may be electrically connected to the active region 118 through a buried contact 170. The landing pads 190 may form the landing pads LP illustrated in FIG. 2.

The landing pads 190 may be on the buried contacts 170, respectively, and may extend on the bit line structures 140, respectively. For example, the lower landing pads 194 may be on the buried contacts 170, respectively, and in contact with side walls of the bit line structures 140. The upper landing pads 196 may be on the lower landing pads 194, respectively, and extend on the bit line structures 140, respectively. For example, the upper landing pads 196 may extend on a bit line structure 140 and cover the cut part 140C (in FIG. 14A) of the bit line structure 140 and the landing pad insulating structure 198 exposed by an inside surface of a second landing pad hole 198H. The cut part 140C of the bit line structures 140 may be in contact with the upper landing pads 196, respectively.

In some embodiments, the top surface of each of the lower landing pads 194 may be at a higher vertical level than the top surface of each of the bit lines 147, i.e., the top surface of each of the second metal conductive patterns 146. In some embodiments, the top surface of each of the upper landing pads 196 may be at the same vertical level as the top surface of the landing pad insulating structure 198. For example, the top surface of each of the upper landing pads 196 may be coplanar with the top surface of the landing pad insulating structure 198.

A plurality of peripheral bit lines BLP may be in contact with the contact plugs CP, respectively. For example, a portion of the bottom surface of each of the peripheral bit lines BLP may be in contact with the top surface of one of the contact plugs CP, and the remaining portion of the bottom surface of each of the peripheral bit lines BLP may be in contact with the second filling insulation layer 174. In some embodiments, the peripheral bit lines BLP may extend inside the upper portion of the second filling insulation layer 174 through the peripheral bit line insulating structure BPS. For example, the bottom surface of each of the peripheral bit lines BLP may be at a lower vertical level than the topmost surface of the second filling insulation layer 174 and the bottom surface of the peripheral bit line insulating structure BPS. In some embodiments, the edge of the bottom surface of each of the peripheral bit lines BLP may have a round shape.

In some embodiments, the top surface of each of the peripheral bit lines BLP may be at the same vertical level as the top surface of the peripheral bit line insulating structure BPS. For example, the top surface of each of the peripheral bit lines BLP may be coplanar with the top surface of the peripheral bit line insulating structure BPS.

In some embodiments, in a process of forming the upper landing pads 196 and the peripheral bit lines BLP by removing an upper portion of the second preliminary conductive material layer 196P, an upper portion of the landing pad insulating structure 198 and an upper portion of the peripheral bit line insulating structure BPS may also be removed such that the vertical level of the top surface of each of the landing pad insulating structure 198 and the peripheral bit line insulating structure BPS may be lower before the upper portion of the second preliminary conductive material layer 196P is removed.

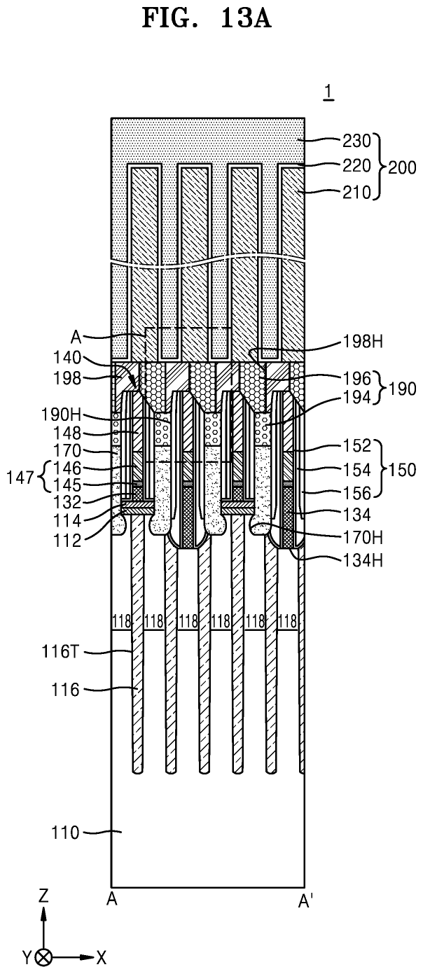

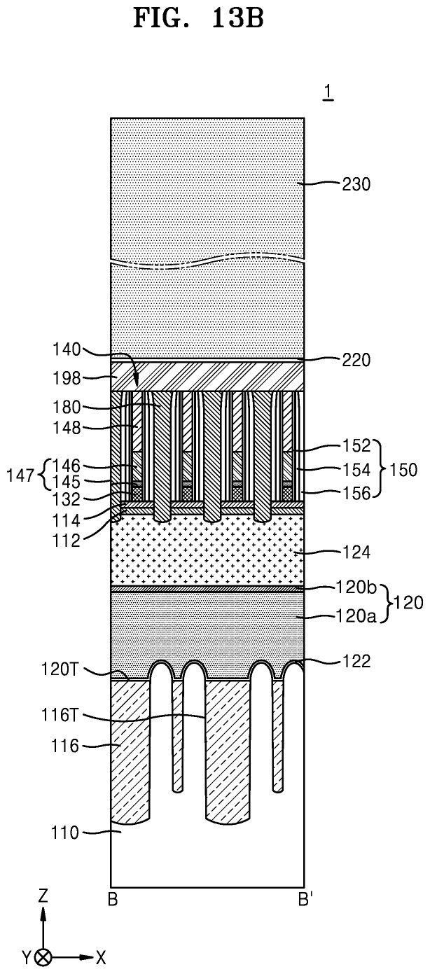

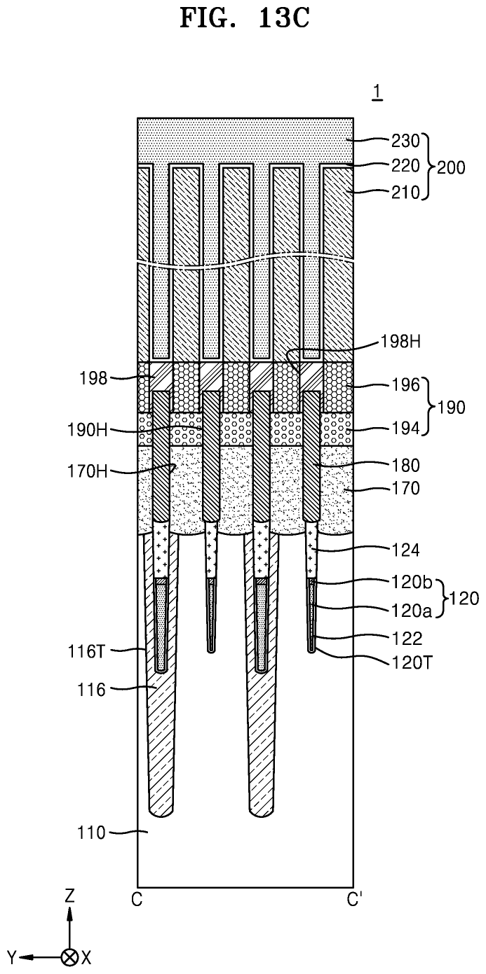

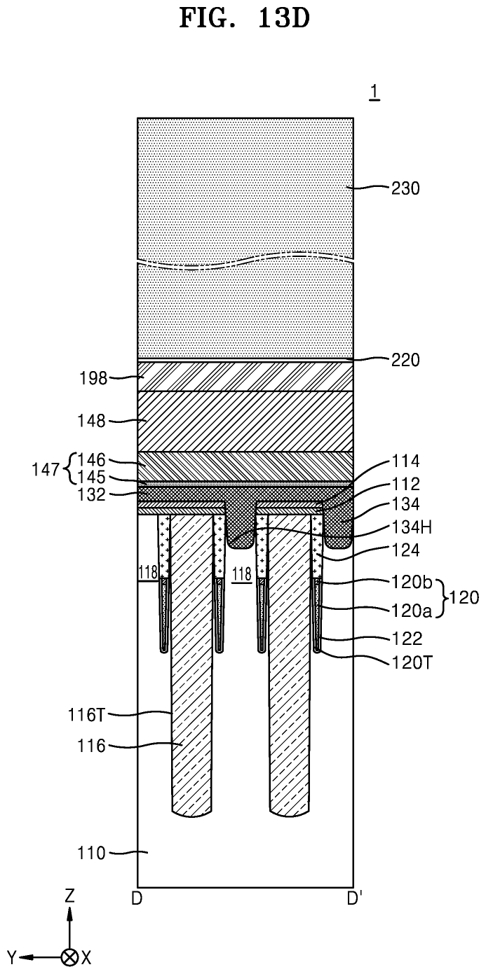

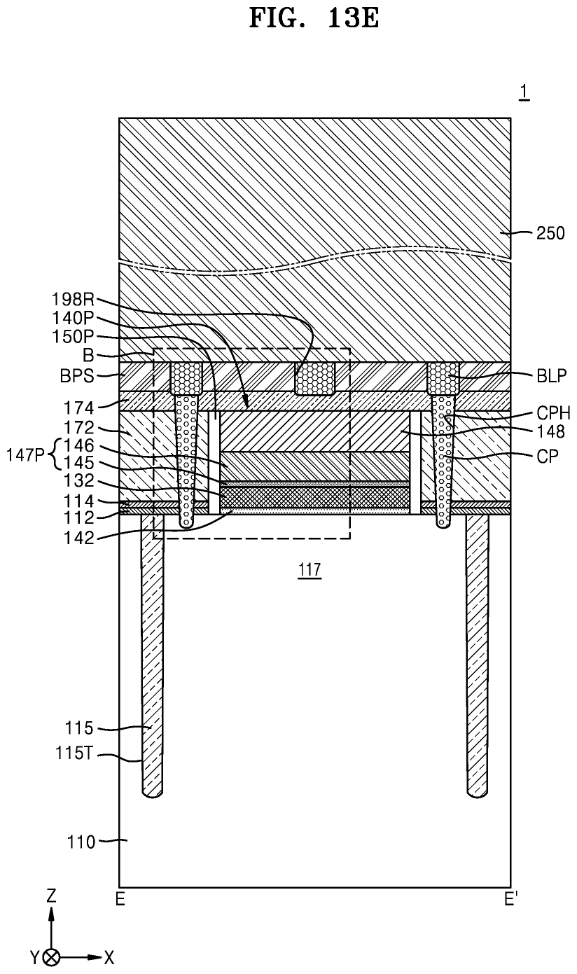

FIGS. 13A to 13E are cross-sectional views of a semiconductor memory device according to embodiments. FIGS. 14A and 14B are enlarged cross-sectional views of respective portions of a semiconductor memory device, according to embodiments. In detail, FIGS. 13A to 13E are cross-sectionals views respectively taken along lines A-A′, B-B′, C-C′, D-D′, and E-E′. FIG. 14A is an enlarged cross-sectional view of a region A in FIG. 13A. FIG. 14B is an enlarged cross-sectional view of a region B in FIG. 13E.

Referring to FIGS. 13A to 14B, a plurality of lower electrodes 210, a capacitor dielectric layer 220, and an upper electrode 230 may be sequentially formed on the landing pads 190, thereby forming the semiconductor memory device 1.

The semiconductor memory device 1 may include a substrate 110 having a plurality of active regions 118 and a peripheral active region 117, a gate dielectric film 122, a word line 120, and a buried insulating film 124, which are sequentially formed in a word line trench 120T crossing the active regions 118 in the substrate 110, an insulating film pattern (including first and second insulating film patterns 112 and 114), which covers an isolation film 116, the active regions 118, and the buried insulating film 124, a plurality of bit line structures 140, each of which includes a bit line 147 and an insulating capping line 148 on the insulating film pattern and insulating spacer structures 150 respectively covering the opposite side walls of each of the bit line 147 and the insulating capping line 148, a plurality of gate line structures 140P, each of which includes a gate line 147P and an insulating capping line 148 on the peripheral active region 117 and gate insulating spacers 150P respectively covering opposite side walls of each of the gate line 147P and the insulating capping line 148, a plurality of buried contacts 170, which fill lower portions of spaces defined by a plurality of insulating fences 180 and the insulating spacer structures 150 and are respectively and electrically connected to the active regions 118, a plurality of landing pads 190, which fill upper portions of the spaces defined by the insulating fences 180 and the insulating spacer structures 150 and extend on the bit line structures 140, and a plurality of capacitor structures 200, each of which includes a lower electrode 210 electrically connected to a landing pad 190, a capacitor dielectric layer 220, and an upper electrode 230.

A plurality of lower electrodes 210, the capacitor dielectric layer 220, and the upper electrode 230 may form a plurality of capacitor structures 200. The capacitor structures 200 including the lower electrodes 210, the capacitor dielectric layer 220, and the upper electrode 230 may be formed in the memory cell region CR (in FIG. 2).

The lower electrodes 210 may be respectively and electrically connected to the landing pads 190. The capacitor dielectric layer 220 may conformally cover the surfaces of the lower electrodes 210. The upper electrode 230 may cover the capacitor dielectric layer 220. In some embodiments, the capacitor dielectric layer 220 and/or the upper electrode 230 may be integrally formed to cover the lower electrodes 210 together in a certain region, e.g., a single memory cell region CR. In some embodiments, the capacitor dielectric layer 220 may cover both the memory cell region CR and the peripheral region PR (in FIG. 2). The lower electrodes 210 may form the storage nodes SN in FIG. 2.

Each of the lower electrodes 210 may have, but not limited to, a solid pillar shape having a circular horizontal cross-section. In some embodiments, each of the lower electrodes 210 may have a cylindrical shape with a closed bottom. In some embodiments, the lower electrodes 210 may be arranged to zigzag in the first horizontal direction (the X direction) or the second horizontal direction (the Y direction) in a honeycomb pattern. In some embodiments, the lower electrodes 210 may be arranged in lines in the first horizontal direction (the X direction) and the second horizontal direction (the Y direction) in a matrix pattern. The lower electrodes 210 may include, for example, impurity-doped silicon, a metal, such as tungsten or copper, or a conductive metal compound, such as titanium nitride. Although not shown, the semiconductor memory device 1 may further include at least one support pattern contacting side walls of the lower electrodes 210.

The capacitor dielectric film 220 may include, for example, TaO, TaAlO, TaON, AlO, AlSiO, HfO, HfSiO, ZrO, ZrSiO, TiO, TiAlO, BST((Ba, Sr)TiO), STO(SrTiO), BTO(BaTiO), PZT(Pb(Zr,Ti)O), (Pb,La)(Zr,Ti)O, Ba(Zr,Ti)O, Sr(Zr,Ti)O, or a combination thereof.

The upper electrode 230 may cover the capacitor dielectric layer 220 and fill spaces among the lower electrodes 210. The upper electrode 230 may include doped silicon, doped polycrystalline silicon germanium (SiGe), or a conductive metal material. For example, the upper electrode 230 may include Ru, RuO, Pt, PtO, Ir, IrO, SRO(SrRuO), BSRO((Ba, Sr)RuO), CRO(CaRuO), BaRuO, La(Sr,Co)O, or the like. In some embodiments, the upper electrode 230 may include metal. For example, the upper electrode 230 may include tungsten (W).

A buried insulating layer 250 may be formed in the peripheral region PR to cover the peripheral bit lines BLP and the peripheral bit line insulating structure BPS. The buried insulating layer 250 may be formed in the peripheral region PR, in which the capacitor structures 200 are not formed, to have a vertical level that is the same as or similar to the vertical level of the capacitor structures 200. For example, the buried insulating layer 250 may include oxide or an ultra-low K (ULK) material. The oxide may include borophosphosilicate glass (BPSG), phosphosilicate glass (PSG), borosilicate glass (BSG), un-doped silicate glass (USG), tetra-ethyl-ortho-silicate (TEOS), or high density plasma (HDP). For example, the ULK material may include one of SiOC and SiCOH, each having an ultra-low dielectric constant K of about 2.2 to about 2.4.

The semiconductor memory device 1 may include the landing pads 190 electrically connecting the buried contacts 170 to the lower electrodes 210. The landing pads 190 may respectively include a plurality of lower landing pads 194 respectively filling a plurality of first landing pad holes 190H and a plurality of upper landing pads 196 respectively filling a plurality of second landing pad holes 198H.

The first landing pad holes 190H may be defined by a plurality of insulating spacer structures 150 and a plurality of insulating fences 180. The buried contacts 170 may be exposed by the bottom surfaces of the first landing pad holes 190H. The second landing pad holes 198H may pass through the landing pad insulating structure 198 to be in communication with the first landing pad holes 190H, respectively.

In a process of forming the second landing pad holes 198H, each of the bit line structures 140 may have the cut part 140C resulting from removal of an upper portion thereof. The cut part 140C may be formed in a portion of each of the bit line structures 140, which is not covered with the landing pad insulating structure 198. For example, opposite portions in the first horizontal direction (the X direction) of each of the bit line structures 140 may be asymmetrical with each other with respect to the second horizontal direction (the Y direction) in which each of the bit line structures 140 extends.

The landing pad insulating structure 198 may cover the top surface of each of the bit line structures 140 and extend along a side wall of each of the bit line structures 140, which does not have the cut part 140C, among opposite side walls in the second horizontal direction (the Y direction) of each of the bit line structures 140. For example, the landing pad insulating structure 198 may have a plurality of insulating grooves 198G extending in lower portions of the landing pad insulating structure 198. The bit line structures 140 may respectively extend in the lower portions of the landing pad insulating structure 198 to respectively fill the insulating grooves 198G.

In some embodiments, the bottommost surface of the landing pad insulating structure 198 may be in contact with each of the lower landing pads 194. For example, the landing pad insulating structure 198 may extend along the side wall of each of the bit line structures 140, which does not have the cut part 140C among the opposite side walls in the second horizontal direction (the Y direction) of each of the bit line structures 140, and may be in contact with each of the lower landing pads 194.

In some embodiments, an upper portion of each of the bit line structures 140, which fills an insulating groove 198G and is covered with the landing pad insulating structure 198, may have a round shape (not illustrated). An upper portion, i.e., the cut part 140C, of each of the bit line structures 140, which is not covered with the landing pad insulating structure 198, may have an oblique shape with a slope.

In some embodiments, the bottom surface of each of the lower landing pads 194 may be at a higher vertical level than the top surface of each of the bit lines 147, i.e., the top surface of each of the second metal conductive patterns 146. The top surface of each of the lower landing pads 194 may be at a lower vertical level than the topmost surface of each of the bit line structures 140.

The peripheral bit lines BLP may be in contact with the contact plugs CP, respectively. For example, a portion of the bottom surface of each of the peripheral bit lines BLP may be in contact with the top surface of one of the contact plugs CP, and the remaining portion of the bottom surface of each of the peripheral bit lines BLP may be in contact with the second filling insulation layer 174. In some embodiments, the peripheral bit lines BLP may extend inside the upper portion of the second filling insulation layer 174 through the peripheral bit line insulating structure BPS. For example, the bottom surface of each of the peripheral bit lines BLP and the top surface of each of the contact plugs CP may be at a first vertical level LV1, and the topmost surface of the second filling insulation layer 174 and the bottom surface of the peripheral bit line insulating structure BPS may be at a second vertical level LV2 that is higher than the first vertical level LV1. The second filling insulation layer 174 may have a plurality of insulating recesses 174R, which respectively correspond to the peripheral bit lines BLP extending inside an upper portion of the second filling insulation layer 174. The bottom surface of each of the insulating recesses 174R may be at the first vertical level LV1.

In some embodiments, each of the peripheral bit lines BLP may have a round part 196R, which has a round shape at the edge of the bottom surface of each peripheral bit line BLP. The second filling insulation layer 174 may have an insulating cut part 174C in a portion of the top surface thereof, which is adjacent to a contact plug CP. The insulating cut part 174C of the second filling insulation layer 174 has a concave shape in correspondence to the round part 196R of the peripheral bit line BLP.

Referring to FIGS. 3A to 14B, because the landing pad insulating structure 198 and the peripheral bit line insulating structure BPS of the semiconductor memory device 1 respectively correspond to a portion of the preliminary insulating material layer 198P, which is patterned in the memory cell region CR, and a portion of the preliminary insulating material layer 198P, which is patterned in the peripheral region PR, the landing pad insulating structure 198 and the peripheral bit line insulating structure BPS may be formed together using a single mask, e.g., a single EUV mask, and may include the same material as each other.

In addition, because the upper landing pads 196 respectively correspond to portions of the second preliminary conductive material layer 196P, which respectively fill the second landing pad holes 198H of the landing pad insulating structure 198, and the peripheral bit lines BLP respectively correspond to portions of the second preliminary conductive material layer 196P, which respectively fill the peripheral bit line recesses 198R of the peripheral bit line insulating structure BPS, the upper landing pads 196 and the peripheral bit lines BLP may be formed together and may include the same material as each other.

Because the landing pads 190 and the peripheral bit lines BLP of the semiconductor memory device 1 are formed not by an embossing method, in which a conductive material is formed and then patterned, but by an engraving method, in which the second landing pad holes 198H and the peripheral bit line recesses 198R are filled, manufacturing processes of the semiconductor memory device 1 may be simplified, and failure, such as bridge or necking, may be prevented from occurring between the landing pads 190. In addition, because the peripheral bit line insulating structure BPS fills between the peripheral bit lines BLP, chemical penetration does not occur in the first filling insulation layer 172 and the second filling insulation layer 174 in a process of forming the peripheral bit lines BLP by using an embossing method, and accordingly, the first filling insulation layer 172 and the second filling insulation layer 174 may be prevented from being damaged.

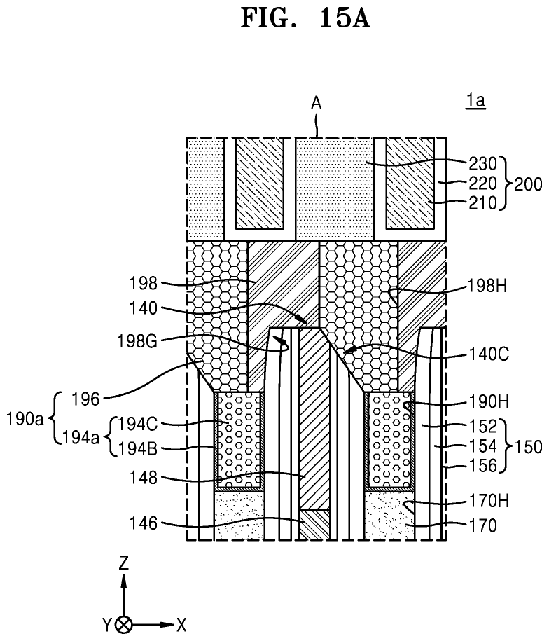

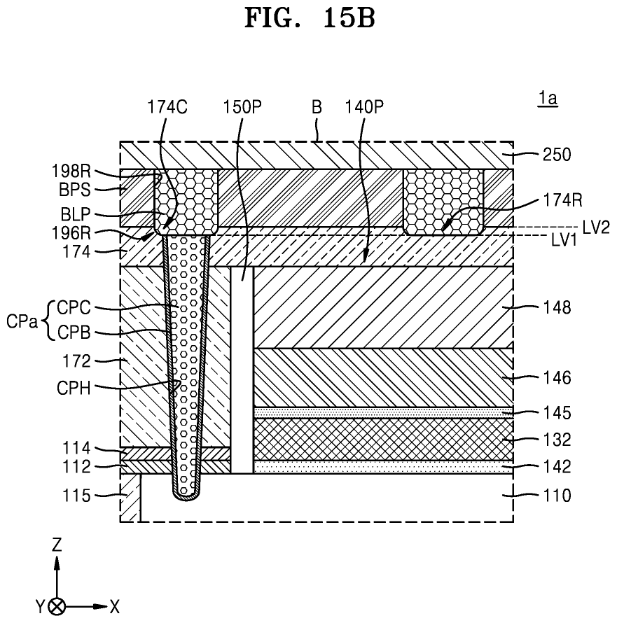

FIGS. 15A and 15B are enlarged cross-sectional views of respective portions of a semiconductor memory device, according to embodiments. In detail, FIG. 15A is an enlarged cross-sectional view of the region A in FIG. 13A, and FIG. 15B is an enlarged cross-sectional view of the region B in FIG. 13E. Redundant descriptions made above with reference to FIGS. 3A to 14B may be omitted below.

Referring to FIGS. 15A and 15B, a semiconductor memory device 1a may include a plurality of landing pads 190a and a plurality of contact plugs CPa, instead of the landing pads 190 and the contact plugs CP included in the semiconductor memory device 1 illustrated in FIGS. 13A to 14B.

The semiconductor memory device 1a may include the landing pads 190a, which respectively and electrically connect the buried contacts 170 to the lower electrodes 210. Each of the landing pads 190a may include a lower landing pad 194a filling a first landing pad hole 190H and an upper landing pad 196 filling a second landing pad hole 198H.

In a process of forming the second landing pad holes 198H, each of the bit line structures 140 may have the cut part 140C resulting from removal of an upper portion thereof. The cut part 140C may be formed in a portion of each of the bit line structures 140, which is not covered with the landing pad insulating structure 198. For example, opposite portions in the first horizontal direction (the X direction) of each of the bit line structures 140 may be asymmetrical with each other with respect to the second horizontal direction (the Y direction) in which each of the bit line structures 140 extends.

The landing pad insulating structure 198 may cover the top surface of each of the bit line structures 140 and extend along a side wall of each of the bit line structures 140, which does not have the cut part 140C, among opposite side walls in the second horizontal direction (the Y direction) of each of the bit line structures 140. For example, the landing pad insulating structure 198 may have a plurality of insulating grooves 198G extending in lower portions of the landing pad insulating structure 198. The bit line structures 140 may respectively extend in the lower portions of the landing pad insulating structure 198 to respectively fill the insulating grooves 198G.

In some embodiments, the bottommost surface of the landing pad insulating structure 198 may be in contact with each of the lower landing pads 194a. For example, the landing pad insulating structure 198 may extend along the side wall of each of the bit line structures 140, which does not have the cut part 140C among the opposite side walls in the second horizontal direction (the Y direction) of each of the bit line structures 140, and may be in contact with each of the lower landing pads 194a.

In some embodiments, an upper portion of each of the bit line structures 140, which fills an insulating groove 198G and is covered with the landing pad insulating structure 198, may have a round shape. An upper portion, i.e., the cut part 140C, of each of the bit line structures 140, which is not covered with the landing pad insulating structure 198, may have an oblique shape with a slope.

Each of the lower landing pads 194a may include a pad barrier layer 194B, which conformally covers the bottom and inside surfaces of the first landing pad hole 190H, and a pad core layer 194C, which covers the pad barrier layer 194B and fills the first landing pad hole 190H. In some embodiments, the pad barrier layer 194B may conformally cover the side and bottom surfaces of the pad core layer 194C. For example, the pad barrier layer 194B may include metal, conductive metal nitride, or a combination thereof. The pad core layer 194C may include metal. In some embodiments, the pad barrier layer 194B may have a stack structure of Ti/TiN. In some embodiments, the pad core layer 194C may include tungsten (W).

A plurality of peripheral bit lines BLP may be in contact with the contact plugs CPa, respectively. For example, a portion of the bottom surface of each of the peripheral bit lines BLP may be in contact with the top surface of a contact plug CPa, and the remaining portion thereof may be in contact with the second filling insulation layer 174. In some embodiments, the peripheral bit lines BLP may pass through the peripheral bit line insulating structure BPS and extend inside an upper portion of the second filling insulation layer 174. For example, the bottom surface of each of the peripheral bit lines BLP and the top surface of each of the contact plugs CPa may be at the first vertical level LV1, and the topmost surface of the second filling insulation layer 174 and the bottom surface of the peripheral bit line insulating structure BPS may be at the second vertical level LV2 that is higher than the first vertical level LV1. The second filling insulation layer 174 may have a plurality of insulating recesses 174R, which respectively correspond to the peripheral bit lines BLP extending inside the upper portion of the second filling insulation layer 174. The bottom surface of each of the insulating recesses 174R may be at the first vertical level LV1.

In some embodiments, each of the peripheral bit lines BLP may have a round part 196R, which has a round shape at the edge of the bottom surface of each peripheral bit line BLP. The second filling insulation layer 174 may have an insulating cut part 174C in a portion of the top surface thereof, which is adjacent to a contact plug CPa. The insulating cut part 174C of the second filling insulation layer 174 has a concave shape in correspondence to the round part 196R of the peripheral bit line BLP.

The contact plugs CPa may respectively fill a plurality of contact holes CPH. Each of the contact plugs CPa may include a contact barrier layer CPB, which conformally covers the bottom and inside surfaces of a contact hole CPH, and a contact core layer CPC, which covers the contact barrier layer CPB and fills the contact hole CPH. In some embodiments, the contact barrier layer CPB may conformally covers the side and bottom surfaces of the contact core layer CPC. In some embodiments, the contact barrier layer CPB and the pad barrier layer 194B may be formed together and may include the same material as each other, and the contact core layer CPC and the pad core layer 194C may be formed together and may include the same material as each other.

For example, the contact barrier layer CPB may include metal, conductive metal nitride, or a combination thereof. In some embodiments, the contact barrier layer CPB may have a stack structure of Ti/TiN. In some embodiments, the contact core layer CPC may include tungsten (W).

While aspects of the inventive concept have been particularly shown and described with reference to embodiments thereof, it will be understood that various changes in form and details may be made therein without departing from the spirit and scope of the following claims.

What is claimed is:

1. A semiconductor memory device comprising:
a substrate including a plurality of active regions in a memory cell region;
a plurality of bit line structures extending in parallel with each other in a first horizontal direction in the memory cell region;
a plurality of buried contacts respectively and electrically connected to the plurality of active regions, the plurality of buried contacts partially filling a space between the plurality of bit line structures;
a plurality of lower landing pads in the space between the plurality of bit line structures and respectively on the plurality of buried contacts;
a landing pad insulating structure in contact with the plurality of bit line structures and the plurality of lower landing pads, the landing pad insulating structure including a plurality of landing pad holes;
a plurality of upper landing pads respectively filling the plurality of landing pad holes and respectively connected to the plurality of lower landing pads; and
a plurality of capacitor structures including a plurality of lower electrodes respectively and electrically connected to the plurality of upper landing pads, an upper electrode, and a capacitor dielectric layer between the plurality of lower electrodes and the upper electrode.

2. The semiconductor memory device of claim 1, wherein the landing pad insulating structure includes a plurality of insulating grooves in a lower portion thereof, the plurality of insulating grooves being respectively filled with the plurality of bit line structures.

3. The semiconductor memory device of claim 2, wherein each of the plurality of bit line structures includes a cut part in an upper portion thereof, the cut part not being covered with the landing pad insulating structure.

4. The semiconductor memory device of claim 3, wherein the cut part of each of the plurality of bit line structures has an oblique shape with a slope, and
another upper portion of each of the plurality of bit line structures fills one of the plurality of insulating grooves and has a round shape.

5. The semiconductor memory device of claim 1, wherein each of the plurality of bit line structures includes a bit line, an insulating capping line covering the bit line, and a pair of insulating spacer structures respectively covering opposite side walls of each of the bit line and the insulating capping line,
a top surface of each of the plurality of lower landing pads is at a lower vertical level than a topmost surface of each of the plurality of bit line structures, and a bottom surface of each of the plurality of lower landing pads is at a higher vertical level than a top surface of the bit line of each of the plurality of bit line structures.

6. The semiconductor memory device of claim 1, further comprising:
a gate line on the substrate in a peripheral region;
a peripheral bit line insulating structure on the gate line, the peripheral bit line insulating structure including a plurality of peripheral bit line recesses and including the same material as the landing pad insulating structure; and
a plurality of peripheral bit lines including the same material as the plurality of upper landing pads and respectively filling the plurality of peripheral bit line recesses, wherein the substrate further includes the peripheral region having a peripheral active region therein.

7. The semiconductor memory device of claim 6, further comprising:
a filling insulation layer in the peripheral region, the filling insulation layer covering the substrate and the gate line and including a plurality of contact holes in communication with the plurality of peripheral bit line recesses, respectively; and
a plurality of contact plugs respectively filling the plurality of contact holes and electrically connected to the peripheral active region,
wherein the plurality of contact plugs include the same material as the plurality of lower landing pads.

8. The semiconductor memory device of claim 7, wherein the plurality of peripheral bit lines pass through the peripheral bit line insulating structure and extend inside an upper portion of the filling insulation layer.

9. The semiconductor memory device of claim 6, wherein a top surface of each of the plurality of upper landing pads is at the same vertical level as a top surface of the landing pad insulating structure, and
a top surface of each of the plurality of peripheral bit lines is at the same vertical level as a top surface of the peripheral bit line insulating structure.

10. The semiconductor memory device of claim 6, wherein a bottom surface of each of the plurality of peripheral bit lines is at a lower vertical level than a bottom surface of the peripheral bit line insulating structure.

11. A semiconductor memory device comprising:
a substrate including a plurality of active regions in a memory cell region and a peripheral active region in a peripheral region;
a plurality of bit line structures extending in parallel with each other in a first horizontal direction in the memory cell region;
a plurality of buried contacts respectively and electrically connected to the plurality of active regions, the plurality of buried contacts partially filling a space between the plurality of bit line structures;
a plurality of lower landing pads in the space between the plurality of bit line structures and respectively on the plurality of buried contacts;
a landing pad insulating structure in contact with the plurality of bit line structures and the plurality of lower landing pads, the landing pad insulating structure including a plurality of landing pad holes;
a plurality of upper landing pads respectively filling the plurality of landing pad holes and respectively connected to the plurality of lower landing pads;
a gate line in the peripheral region;
a peripheral bit line insulating structure on the gate line, the peripheral bit line insulating structure including a plurality of peripheral bit line recesses; and
a plurality of peripheral bit lines respectively filling the plurality of peripheral bit line recesses,
wherein a top surface of each of the plurality of upper landing pads, a top surface of the landing pad insulating structure, a top surface of each of the plurality of peripheral bit lines, and a top surface of the peripheral bit line insulating structure are coplanar with one another at the same vertical level.

12. The semiconductor memory device of claim 11, further comprising:
a filling insulation layer in the peripheral region, the filling insulation layer covering the substrate and the gate line and including a plurality of contact holes in communication with the plurality of peripheral bit line recesses, respectively; and
a plurality of contact plugs respectively filling the plurality of contact holes and electrically connected to the peripheral active region.

13. The semiconductor memory device of claim 12, wherein the plurality of peripheral bit lines pass through the peripheral bit line insulating structure and extend inside an upper portion of the filling insulation layer, and
a bottom surface of each of the plurality of peripheral bit lines is at a lower vertical level than a bottom surface of the peripheral bit line insulating structure.

14. The semiconductor memory device of claim 13, wherein the bottom surface of each of the plurality of peripheral bit lines is at the same vertical level as a top surface of each of the plurality of contact plugs.

15. The semiconductor memory device of claim 13, wherein the landing pad insulating structure includes a plurality of insulating grooves in a lower portion thereof, the plurality of insulating grooves being respectively filled with the plurality of bit line structures, and
each of the plurality of bit line structures includes a cut part in an upper portion thereof, the cut part not being covered with the landing pad insulating structure.

16. The semiconductor memory device of claim 12, wherein the landing pad insulating structure includes the same material as the peripheral bit line insulating structure,
the plurality of upper landing pads include the same material as the plurality of peripheral bit lines, and
the plurality of lower landing pads include the same material as the plurality of contact plugs.

17. The semiconductor memory device of claim 11, wherein a bottom surface of each of the plurality of upper landing pads and a top surface of the plurality of lower landing pads are at a lower vertical level than a topmost surface of each of the plurality of bit line structures, and
the top surface of each of the plurality of upper landing pads is at a higher vertical level than the topmost surface of each of the plurality of bit line structures.

18. A semiconductor memory device comprising:
a substrate including a plurality of active regions in a memory cell region and a peripheral active region in a peripheral region;
a plurality of word lines respectively in a plurality of word line trenches in the substrate, the plurality of word line trenches extending in parallel with each other in a first horizontal direction in the memory cell region;
a plurality of bit line structures extending on the plurality of word lines in parallel with each other in a second horizontal direction that is perpendicular to the first horizontal direction, wherein each of the plurality of bit line structures includes a bit line, an insulating capping line covering the bit line, and a pair of insulating spacer structures respectively covering opposite side walls of each of the bit line and the insulating capping line;
a plurality of buried contacts respectively and electrically connected to the plurality of active regions, the plurality of buried contacts partially filling a space between the plurality of bit line structures;
a plurality of lower landing pads in the space between the plurality of bit line structures and respectively on the plurality of buried contacts;
a landing pad insulating structure in contact with the plurality of bit line structures and the plurality of lower landing pads, the landing pad insulating structure including a plurality of landing pad holes;
a plurality of upper landing pads respectively filling the plurality of landing pad holes and respectively connected to the plurality of lower landing pads;
a plurality of capacitor structures including a plurality of lower electrodes respectively and electrically connected to the plurality of upper landing pads, an upper electrode, and a capacitor dielectric layer between the plurality of lower electrodes and the upper electrode;
a gate line in the peripheral region;
a filling insulation layer in the peripheral region, the filling insulation layer covering the substrate and the gate line and including a plurality of contact holes;
a plurality of contact plugs respectively filling the plurality of contact holes and electrically connected to the peripheral active region;
a peripheral bit line insulating structure on the gate line, the peripheral bit line insulating structure including a plurality of peripheral bit line recesses in communication with the plurality of contact holes, respectively; and
a plurality of peripheral bit lines respectively filling the plurality of peripheral bit line recesses and electrically connected to the plurality of contact plugs,
wherein the landing pad insulating structure includes a plurality of insulating grooves in a lower portion thereof, the plurality of insulating grooves being respectively filled with the plurality of bit line structures, and
the plurality of peripheral bit lines pass through the peripheral bit line insulating structure and extend inside an upper portion of the filling insulation layer.

19. The semiconductor memory device of claim 18, wherein a top surface of each of the plurality of upper landing pads, a top surface of the landing pad insulating structure, a top surface of each of the plurality of peripheral bit lines, and a top surface of the peripheral bit line insulating structure are coplanar with one another at the same vertical level,
a bottom surface of each of the plurality of upper landing pads and a top surface of the plurality of lower landing pads are at a lower vertical level than a topmost surface of each of the plurality of bit line structures, and
a bottom surface of the plurality of lower landing pads is at a higher vertical level than a top surface of the bit line of each of the plurality of bit line structures.

20. The semiconductor memory device of claim 18, wherein the landing pad insulating structure and the peripheral bit line insulating structure include silicon nitride, and
the plurality of upper landing pads and the plurality of peripheral bit lines include tungsten.
